(19) United States
(12) Patent Application Publication
(10) Pub. No.: US 2026/0059752 A1
(43) Pub. Date: Feb. 26, 2026

(54) SEMICONDUCTOR DEVICE AND METHOD OF FABRICATING THE SAME

(71) Applicant: Samsung Electronics Co., Ltd., Suwon-si (KR)

(72) Inventors: Hyun Jun AHN, Suwon-si (KR); KWANGMOON KIM, Suwon-si (KR); HEEHWAN NOH, Suwon-si (KR)

(21) Appl. No.: 19/054,453

(22) Filed: Feb. 14, 2025

(30) Foreign Application Priority Data
Aug. 22, 2024 (KR) 10-2024-0113033

(51) Int. Cl. H10B 43/27; H01L 23/00; H01L 25/18; H10B 43/10; H10B 43/35; H10B 43/40; H10B 80/00; H10D 80/30

(52) U.S. Cl. CPC H10B 43/27; H01L 25/18; H10B 43/10; H10B 43/35; H10B 43/40; H10B 80/00; H10D 80/30; H01L 24/32; H01L 24/48; H01L 2224/32145; H01L 2224/32225; H01L 2224/48147; H01L 2224/48227; H01L 2225/06506; H01L 2225/0651; H01L 2225/06524; H01L 2225/06562; H01L 2924/1438

(57) ABSTRACT

A method of fabricating a semiconductor device may include forming a lower mold structure on a substrate, forming a first mold structure on the lower mold structure, the first mold structure including first interlayer insulating layers and first sacrificial layers, which are alternately stacked in a vertical direction, forming first vertical channel holes to penetrate the first mold structure, the lower mold structure, and a portion of the substrate, and forming an active layer to cover a top surface of the first mold structure and extend to an upper side surface of each of the first vertical channel holes. The active layer may include a horizontal portion covering the top surface of the first mold structure and a vertical portion covering the upper side surface of each of the first vertical channel holes, and the active layer may include a metallic material.

### CROSS-REFERENCE TO RELATED APPLICATION(S)

This U.S. non-provisional patent application claims priority under 35 U.S.C. § 119 to Korean Patent Application No. 10-2024-0113033, filed on Aug. 22, 2024, in the Korean Intellectual Property Office, the disclosure of which is incorporated by reference herein in its entirety.

### BACKGROUND OF THE INVENTION

The present disclosure relates to a semiconductor device and an electronic system including the same, and in particular, a nonvolatile semiconductor memory device including a vertical channel structure, a method of fabricating the same, and an electronic system including the same.

A semiconductor device capable of storing a large amount of data is required as a part of an electronic system. Higher integration of semiconductor devices is required to satisfy consumer demands for large data storing capacity, superior performance, and inexpensive prices. In the case of two-dimensional or planar semiconductor devices, since their integration is mainly determined by the area occupied by a unit memory cell, integration is greatly influenced by the level of a fine pattern forming technology. However, the extremely expensive process equipment needed to increase pattern fineness sets a practical limitation on increasing integration for two-dimensional or planar semiconductor devices. Thus, three-dimensional semiconductor memory devices including three-dimensionally arranged memory cells have recently been proposed.

### SUMMARY

An embodiment of the inventive concept provides a semiconductor device with improved electrical and reliability characteristics and a method of fabricating the same.

An embodiment of the inventive concept provides an electronic system including the semiconductor device.

According to an embodiment of the inventive concept, a method of fabricating a semiconductor device may include forming a lower mold structure on a substrate, forming a first mold structure on the lower mold structure, the first mold structure including first interlayer insulating layers and first sacrificial layers, which are alternately stacked in a vertical direction, forming first vertical channel holes to penetrate the first mold structure, the lower mold structure, and a portion of the substrate, and forming an active layer to cover a top surface of the first mold structure and extend to an upper side surface of each of the first vertical channel holes. The active layer may include a horizontal portion covering the top surface of the first mold structure and a vertical portion covering the upper side surface of each of the first vertical channel holes, and the active layer may include a metallic material.

According to an embodiment of the inventive concept, a method of fabricating a semiconductor device may include forming a first mold structure on a substrate, the first mold structure including first interlayer insulating layers and first sacrificial layers alternately stacked in a vertical direction, forming a first vertical channel hole to penetrate the first mold structure, and forming an active layer to cover a top surface of the first mold structure and extend to an upper side surface of the first vertical channel hole. The active layer may include a horizontal portion covering the top surface of the first mold structure and a vertical portion covering the upper side surface of each of the first vertical channel holes, and a width of the vertical portion, which is measured in a horizontal direction parallel to a top surface of the substrate, may increase as a distance from the substrate increases.

According to an embodiment of the inventive concept, a method of fabricating a semiconductor device may include forming a first mold structure on a substrate to include first interlayer insulating layers and first sacrificial layers alternately stacked in a vertical direction, forming first vertical channel holes to penetrate the first mold structure and a portion of the substrate, forming an active layer to cover a top surface of the first mold structure and extend to an upper side surface of each of the first vertical channel holes, forming a mold sacrificial layer on the active layer to fill an upper portion of each of the first vertical channel holes, forming a void in a remaining portion of each of the first vertical channel holes, forming a second mold structure on the first mold structure to include second interlayer insulating layers and second sacrificial layers alternately stacked in the vertical direction, after removing the active layer and the mold sacrificial layer from the top surface of the first mold structure, forming second vertical channel holes to penetrate the second mold structure and each of the second vertical channel holes vertically overlapped with each of the first vertical channel holes, forming a first stack by filling empty spaces formed by removing the first sacrificial layers to include the first interlayer insulating layers and first gate electrodes alternately stacked in the vertical direction, and forming a second stack by filling empty spaces formed by removing the second sacrificial layers to include the second interlayer insulating layers and second gate electrodes alternately stacked in the vertical direction.

### BRIEF DESCRIPTION OF THE DRAWINGS

FIG. 1 is a diagram schematically illustrating an electronic system including a semiconductor device according to an embodiment of the inventive concept.

FIG. 2 is a perspective view schematically illustrating an electronic system including a semiconductor device, according to an embodiment of the inventive concept.

FIGS. 3 and 4 are sectional views, which are respectively taken along lines I-I′ and II-II′ of FIG. 2 to illustrate a semiconductor package including a semiconductor device according to an embodiment of the inventive concept.

FIG. 5 is a plan view illustrating a semiconductor device according to an embodiment of the inventive concept.

FIGS. 6A and 6B are sectional views, which are respectively taken along lines A-A′ and B-B′ of FIG. 5 to illustrate a semiconductor device according to an embodiment of the inventive concept.

FIGS. 7A and 7B are enlarged sectional views illustrating a portion (e.g., ‘A’ and ‘B’ of FIG. 6A, respectively) of a semiconductor device according to an embodiment of the inventive concept.

FIG. 8 is an enlarged sectional view illustrating a portion (e.g., ‘B’ of FIG. 6A) of a semiconductor device according to an embodiment of the inventive concept.

FIGS. 9A, 9B, 10A to 10D, 11A to 11H, 12A to 12D, and 13 to 23 are sectional views illustrating a method of fabricating a semiconductor device, according to an embodiment of the inventive concept.

FIG. 24 is a plan view illustrating a semiconductor device according to an embodiment of the inventive concept.

FIGS. 25A and 25B are sectional views, which are respectively taken along lines A-A′ and B-B′ of FIG. 24 to illustrate a semiconductor device according to an embodiment of the inventive concept.

### DETAILED DESCRIPTION

Example embodiments of the inventive concepts will now be described more fully with reference to the accompanying drawings, in which example embodiments are shown.

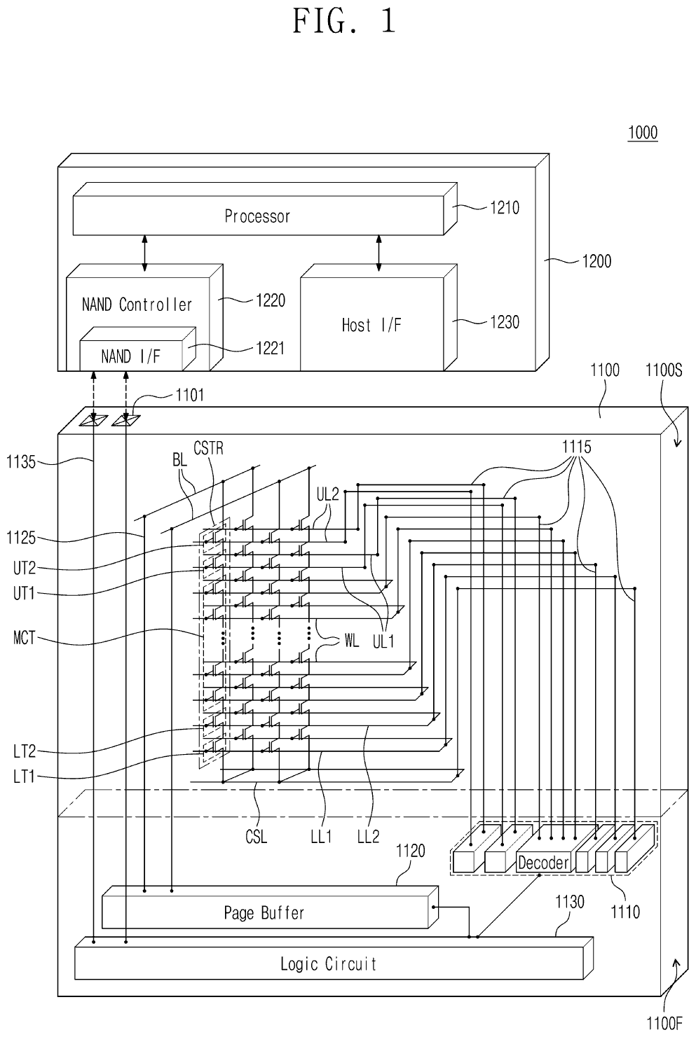

FIG. 1 is a diagram schematically illustrating an electronic system including a three-dimensional semiconductor memory device, according to an embodiment of the inventive concept.

Referring to FIG. 1, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB) device, a computing system, a medical system, or a communication system, in which at least one three-dimensional semiconductor memory devices 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. For example, the first region 1100F may be disposed near the second region 1100S. The first region 1100F may be a peripheral circuit region, which includes a decoder circuit 1110, a page buffer 1120, and a logic circuit 1130. The second region 1100S may be a memory cell region, which includes a bit line BL, a common source line CSL, word lines WL, first lines LL1 and LL2, second lines UL1 and UL2, and memory cell strings CSTR between the bit line BL and the common source line CSL.

In the second region 1100S, each of the memory cell strings CSTR may include first transistors LT1 and LT2 adjacent to the common source line CSL, second transistors UT1 and UT2 adjacent to the bit line BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments.

For example, each of the memory cell transistors MCT may include a data storing element containing a ferroelectric material. By using the data storing element containing the ferroelectric material, it may be possible to realize a three-dimensional semiconductor memory device that can be operated with relatively low power and with a fast operation speed. The word lines WL may serve as gate electrodes of the memory cell transistors MCT. A voltage difference between the word lines WL and channel regions of the memory cell transistors MCT may be adjusted to cause a change in polarization of a dipole of the ferroelectric material, and this may be used to perform a data writing or erasing operation on the memory cell transistors MCT.

In an embodiment, the first transistors LT1 and LT2 may include a ground selection transistor, and the second transistors UT1 and UT2 may include a string selection transistor. The first lines LL1 and LL2 may serve as gate electrodes of the first transistors LT1 and LT2, respectively. The word lines WL may serve as gate electrodes of the memory cell transistors MCT. The second lines UL1 and UL2 may serve as gate electrodes of the second transistors UT1 and UT2, respectively.

The common source line CSL, the first lines LL1 and LL2, the word lines WL, and the second lines UL1 and UL2 may be electrically connected to the decoder circuit 1110 through first interconnection lines 1115, which are extended from the first region 1100F to the second region 1100S. The bit line BL may be electrically connected to the page buffer 1120 through second interconnection lines 1125, which are extended from the first region 1100F to the second region 1100S.

In the first region 1100F, the decoder circuit 1110 and the page buffer 1120 may be configured to perform a control operation, which is performed on at least one selected one of the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may control the plurality of three-dimensional semiconductor memory devices 1100.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands, which are used to control the three-dimensional semiconductor memory device 1100, data, which will be written in or read from the memory cell transistors MCT of the three-dimensional semiconductor memory device 1100, and so forth. The host interface 1230 may be configured to allow for communication between the electronic system 1000 and an external host. If a control command is received from an external host through the host interface 1230, the processor 1210 may control the three-dimensional semiconductor memory device 1100 in response to the control command.

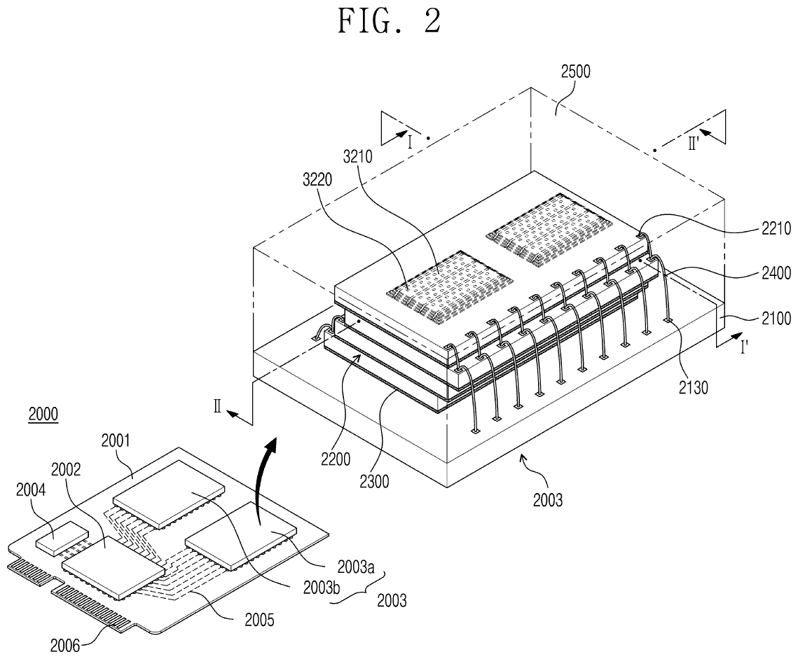

FIG. 2 is a perspective view schematically illustrating an electronic system including a three-dimensional semiconductor memory device, according to an embodiment of the inventive concept.

Referring to FIG. 2, an electronic system 2000 may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 and to each other by interconnection patterns 2005, which are provided in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In an embodiment, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC), which is used to distribute a power supplied from the external host to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and the external host. In an embodiment, the DRAM 2004 in the electronic system 2000 may serve as a cache memory and may provide a storage space, which data are temporarily stored, during various control operations performed on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacks 3210 and vertical channel structures 3220. Each of the semiconductor chips 2200 may include a three-dimensional semiconductor memory device, which will be described below.

In an embodiment, the connection structure 2400 may be a bonding wire electrically connecting the input/output pads 2210 to the package upper pads 2130. In each of the first and second semiconductor packages 2003a and 2003b, the semiconductor chips 2200 may be electrically connected to each other in a bonding wire manner and may be electrically connected to the package upper pads 2130 of the package substrate 2100. In an embodiment, the semiconductor chips 2200 in each of the first and second semiconductor packages 2003a and 2003b may be electrically connected to each other by through silicon vias (TSVs), not by the connection structure 2400 provided in the form of bonding wires.

In an embodiment, the controller 2002 and the semiconductor chips 2200 may be included in a single package. For example, the controller 2002 and the semiconductor chips 2200 may be mounted on an interposer substrate, which is prepared independent of the main substrate 2001, and may be connected to each other through interconnection lines, which are provided in the interposer substrate.

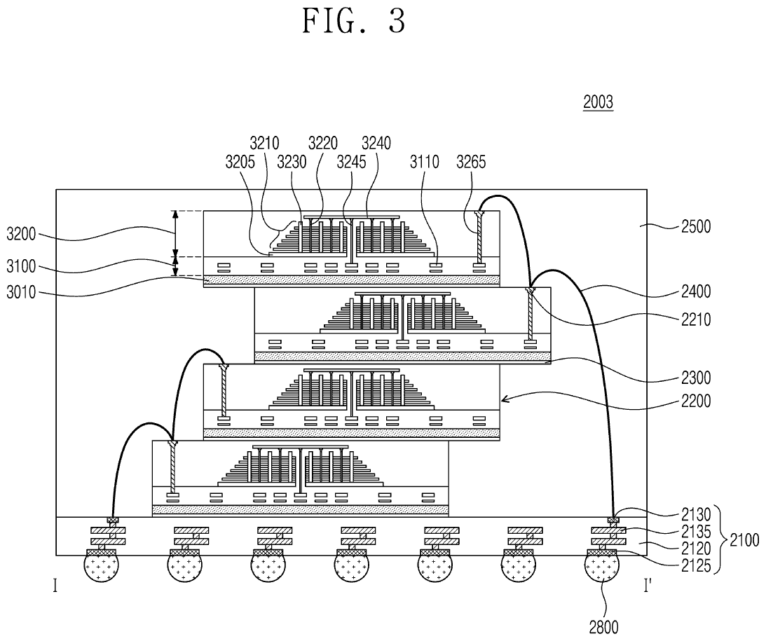

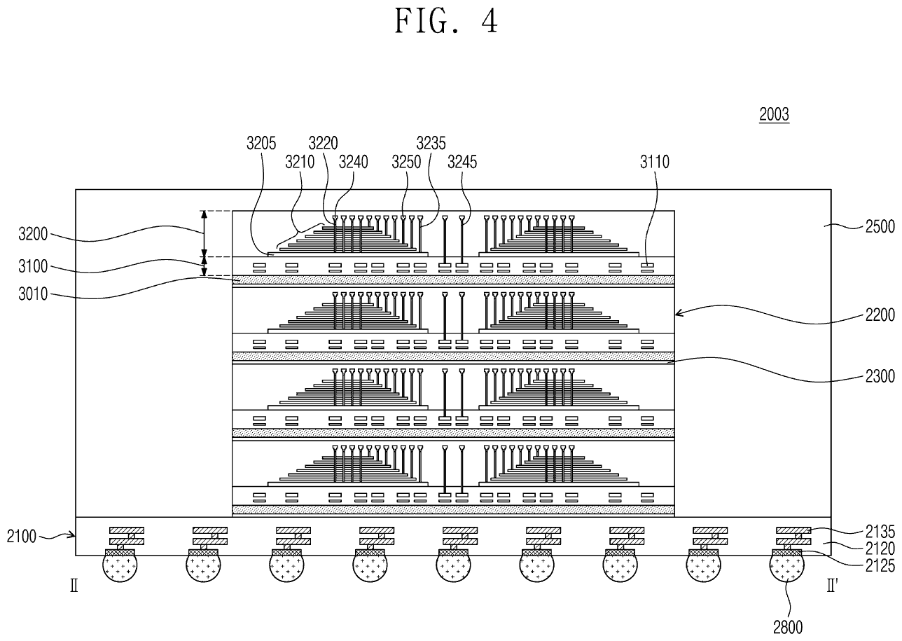

FIGS. 3 and 4 are sectional views, which are respectively taken along lines I-I′ and II-II′ of FIG. 2 to illustrate a semiconductor package including a three-dimensional semiconductor memory device, according to an embodiment of the inventive concept.

Referring to FIGS. 3 and 4, the semiconductor package 2003 may include the package substrate 2100, a plurality of semiconductor chips on the package substrate 2100, and the molding layer 2500 covering the package substrate 2100 and the semiconductor chips.

The package substrate 2100 may include a package substrate body portion 2120, the package upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The package upper pads 2130 may be electrically connected to the connection structures 2400. The lower pads 2125 may be connected to the interconnection patterns 2005 of the main substrate 2001 of the electronic system 2000 shown in FIG. 2 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region, in which peripheral lines 3110 are provided. The second structure 3200 may include a common source line 3205, the gate stack 3210 on the common source line 3205, the vertical channel structures 3220 and separation structures 3230 penetrating the gate stack 3210, bit lines 3240 electrically connected to the vertical channel structures 3220, gate connection lines 3235 electrically connected to the word lines WL (e.g., see FIG. 1) of the gate stack 3210, and conductive lines 3250.

Each of the semiconductor chips 2200 may be electrically connected to the peripheral lines 3110 of the first structure 3100 and may include a penetration line 3245, which is extended into the second structure 3200. The penetration line 3245 may be provided to penetrate the gate stack 3210 and may be disposed outside the gate stack 3210. Each of the semiconductor chips 2200 may further include an input/output connection line 3265, which is extended into the second structure 3200, and the input/output pad 2210, which is electrically connected to the input/output connection line 3265.

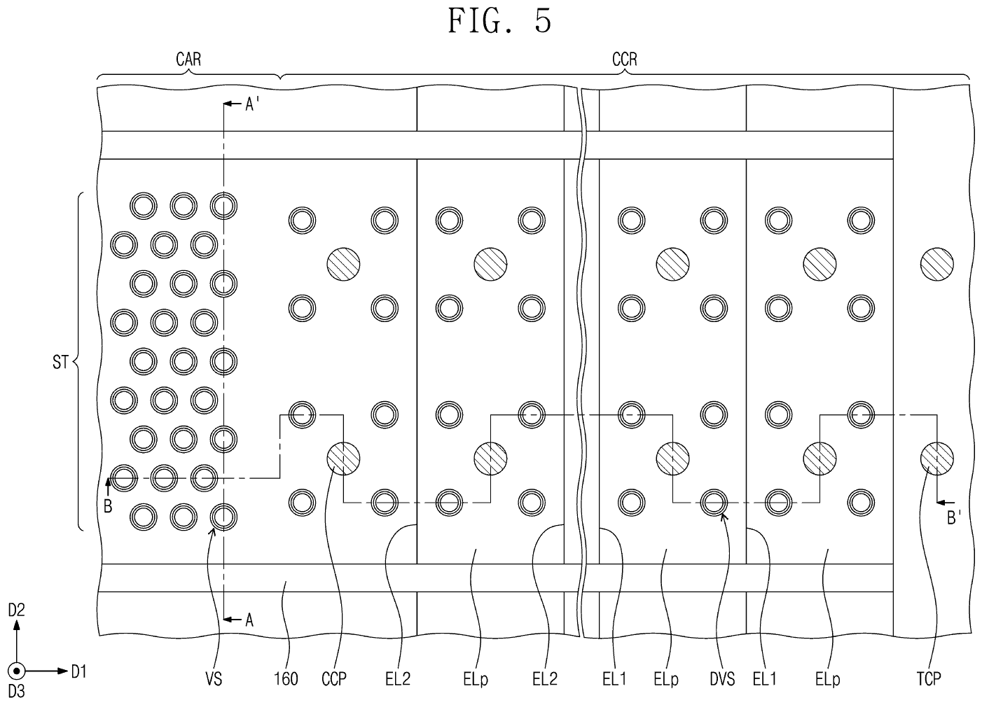

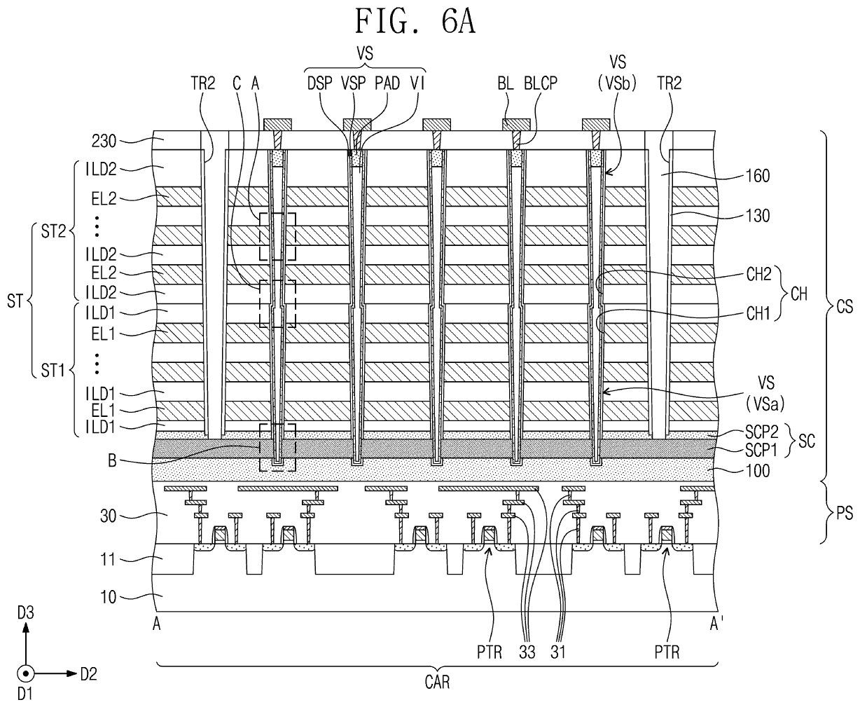

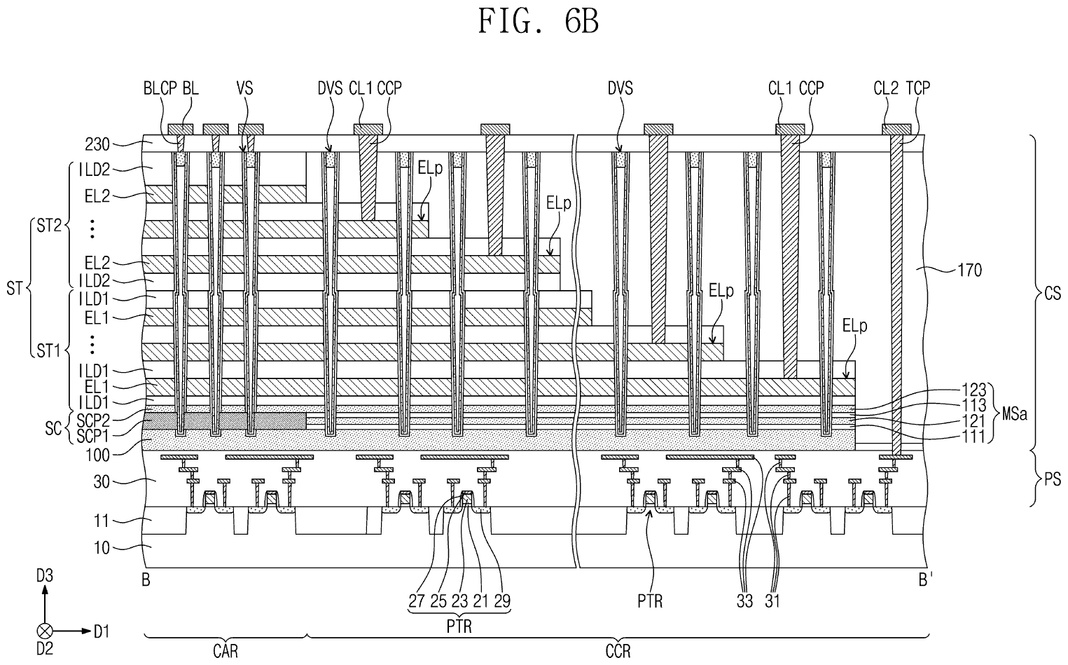

FIG. 5 is a plan view illustrating a semiconductor device according to an embodiment of the inventive concept. FIGS. 6A and 6B are sectional views, which are respectively taken along lines A-A′ and B-B′ of FIG. 5 to illustrate a semiconductor device according to an embodiment of the inventive concept.

Referring to FIGS. 5, 6A, and 6B, a semiconductor device may include a peripheral substrate 10, a peripheral circuit structure PS on the peripheral substrate 10, and a cell array structure CS on the peripheral circuit structure PS. The peripheral substrate 10, the peripheral circuit structure PS, and the cell array structure CS may correspond to the semiconductor substrate 3010, the first structure 3100 on the semiconductor substrate 3010, and the second structure 3200 on the first structure 3100, respectively, which are illustrated in FIGS. 3 and 4.

The peripheral substrate 10 may include a cell array region CAR and a contact region CCR. The peripheral substrate 10 may be extended from the cell array region CAR toward the contact region CCR in first and second directions D1 and D2, which are not parallel to each other. The first and second directions D1 and D2 may be parallel to a top surface of the peripheral substrate 10 and may be orthogonal to each other. A third direction D3 may be a vertical direction D3 perpendicular to the top surface of the peripheral substrate 10. For example, the first, second, and third directions D1, D2, and D3 may be orthogonal to each other.

When viewed in a plan view, the contact region CCR may be extended from the cell array region CAR in the first direction D1 or an opposite direction of the first direction D1. The cell array region CAR may be a region, on which the vertical channel structures 3220 described with reference to FIGS. 3 and 4, the separation structures 3230, and the bit lines 3240 electrically connected to the vertical channel structures 3220 are provided. The contact region CCR may be a region, on which a stepwise structure including pad portions ELp to be described below is provided. Unlike that illustrated in the drawings, the contact region CCR may be extended from the cell array region CAR in the second direction D2 or an opposite direction of the second direction D2.

In an embodiment, the peripheral substrate 10 may be a silicon substrate, a silicon-germanium substrate, a germanium substrate, or a structure including a single-crystalline silicon substrate and a single crystalline epitaxial layer grown therefrom. A device isolation layer 11 may be provided in the peripheral substrate 10. The device isolation layer 11 may define an active region of the peripheral substrate 10. The device isolation layer 11 may be formed of or include, for example, silicon oxide.

The peripheral circuit structure PS may be provided on the peripheral substrate 10. The peripheral circuit structure PS may include peripheral circuit transistors PTR on the active region of the peripheral substrate 10, peripheral contact plugs 31, peripheral circuit interconnection lines 33 electrically connected to the peripheral circuit transistors PTR through the peripheral contact plugs 31, and a first insulating layer 30 enclosing them. The peripheral circuit structure PS may correspond to the first region 1100F of FIG. 1, and the peripheral circuit interconnection lines 33 may correspond to the peripheral lines 3110 of FIGS. 3 and 4.

The peripheral circuit transistors PTR, the peripheral contact plugs 31, and the peripheral circuit interconnection lines 33 may constitute a peripheral circuit. For example, the peripheral circuit transistors PTR may constitute the decoder circuit 1110, the page buffer 1120, and the logic circuit 1130 of FIG. 1. More specifically, each of the peripheral circuit transistors PTR may include a peripheral gate insulating layer 21, a peripheral gate electrode 23, a peripheral capping pattern 25, a peripheral gate spacer 27, and peripheral source/drain regions 29.

The peripheral gate insulating layer 21 may be provided between the peripheral gate electrode 23 and the peripheral substrate 10. The peripheral gate capping pattern 25 may be provided on the peripheral gate electrode 23. The peripheral gate spacer 27 may cover side surfaces of the peripheral gate insulating layer 21, the peripheral gate electrode 23, and the peripheral gate capping pattern 25. The peripheral source/drain regions 29 may be provided in portions of the peripheral substrate 10, which are located at both sides of the peripheral gate electrode 23.

The peripheral circuit interconnection lines 33 may be electrically connected to the peripheral circuit transistors PTR through the peripheral contact plugs 31. Each of the peripheral circuit transistors PTR may be an n-type metal oxide semiconductor (NMOS) transistor or a p-type metal oxide semiconductor (PMOS) transistor and, in an embodiment, it may be a gate-all-around type transistor. A width of each of the peripheral contact plugs 31 in the first or second direction D1 or D2 may increase with increasing distance from the peripheral substrate 10. The peripheral contact plugs 31 and the peripheral circuit interconnection lines 33 may be formed of or include at least one of conductive materials (e.g., metallic materials).

The first insulating layer 30 may be provided on the top surface of the peripheral substrate 10. The first insulating layer 30 may be provided on the peripheral substrate 10 to cover the peripheral circuit transistors PTR, the peripheral contact plugs 31, and the peripheral circuit interconnection lines 33. The first insulating layer 30 may have a multi-layered structure including a plurality of insulating layers. For example, the first insulating layer 30 may include at least one of silicon oxide, silicon nitride, silicon oxynitride, and/or low-k dielectric materials.

The cell array structure CS may be provided on the first insulating layer 30, and here, the cell array structure CS may include a substrate 100 and a stack ST on the substrate 100. The substrate 100 may be extended in the first and second directions D1 and D2. The substrate 100 may not be provided on a portion of the contact region CCR. The substrate 100 may be a semiconductor substrate including a semiconductor material. The substrate 100 may be formed of or include at least one of silicon (Si), germanium (Ge), silicon germanium (SiGe), gallium arsenic (GaAs), indium gallium arsenic (InGaAs), and aluminum gallium arsenic (AlGaAs).

The stack ST may be provided on the substrate 100. The stack ST may be extended from the cell array region CAR to the contact region CCR. The stack ST may correspond to the gate stacks 3210 of FIGS. 3 and 4. In an embodiment, a plurality of the stacks ST may be arranged in the second direction D2 and may be spaced apart from each other in the second direction D2 with a separation structure 160 interposed therebetween. For brevity's sake, just one stack ST will be described below, but the others of the stacks ST may also have substantially the same features as described below.

The stack ST may include interlayer insulating layers ILD1 and ILD2 and gate electrodes EL1 and EL2, which are alternately stacked. The gate electrodes EL1 and EL2 may correspond to the word lines WL, the first lines LL1 and LL2, and the second lines UL1 and UL2 of FIG. 1.

In an embodiment, the stack ST may include a first stack ST1 on the substrate 100 and a second stack ST2 on the first stack ST1. The first stack ST1 may include first interlayer insulating layers ILD1 and first gate electrodes EL1, which are alternately stacked, and the second stack ST2 may include second interlayer insulating layers ILD2 and second gate electrodes EL2, which are alternately stacked. The first and second gate electrodes EL1 and EL2 may have substantially the same thickness in the third direction D3. Hereinafter, the term ‘thickness’ may be used to represent a length of an element measured in the third direction D3.

As a height from the substrate 100 (i.e., in the third direction D3) increases, a length of each of the first and second gate electrodes EL1 and EL2 in the first direction D1 may decrease. For example, the length of each of the first and second gate electrodes EL1 and EL2 in the first direction D1 may be larger than a length of another electrode thereon in the first direction D1. The lowermost one of the first gate electrodes EL1 of the first stack ST1 may have the longest length in the first direction D1, and the uppermost one of the second gate electrodes EL2 of the second stack ST2 may have the shortest length in the first direction D1.

The first and second gate electrodes EL1 and EL2 may have the pad portions ELp, on the contact region CCR. The pad portions ELp of the first and second gate electrodes EL1 and EL2 may be disposed at positions that are different from each other in horizontal and vertical directions. The pad portions ELp may form a stepwise structure in the first direction D1.

Due to the stepwise structure, each of the first and second stacks ST1 and ST2 may have a decreasing thickness, as a distance from the outermost one of vertical channel structures VS to be described below increases, and side surfaces of the first and second gate electrodes EL1 and EL2 may be spaced apart from each other in the first direction D1 by a specific distance, when viewed in a plan view.

The first and second gate electrodes EL1 and EL2 may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), and transition metals (e.g., titanium, tantalum, and so forth). In an embodiment, the first and second gate electrodes EL1 and EL2 may be formed of or include tungsten.

The first and second interlayer insulating layers ILD1 and ILD2 may be provided between the first and second gate electrodes EL1 and EL2, and each of them may have a side surface that is aligned to a side surface of a corresponding one of the first and second gate electrodes EL1 and EL2, which is disposed thereunder and is in contact with the same. For example, the first and second interlayer insulating layers ILD1 and ILD2 may be provided such that a length in the first direction D1 decreases with increasing distance from the substrate 100, similar to the first and second gate electrodes EL1 and EL2.

The lowermost one of the second interlayer insulating layers ILD2 may be in contact with the uppermost one of the first interlayer insulating layers ILD1. For example, a thickness of each of the first and second interlayer insulating layers ILD1 and ILD2 may be smaller than a thickness of each of the first and second gate electrodes EL1 and EL2. For example, a thickness of the lowermost one of the first interlayer insulating layers ILD1 may be smaller than a thickness of each of the others of the interlayer insulating layers ILD1 and ILD2. For example, a thickness of the uppermost one of the second interlayer insulating layers ILD2 may be larger than the thickness of each of the others of the interlayer insulating layers ILD1 and ILD2.

Except for the lowermost one of the first interlayer insulating layers ILD1 and the uppermost one of the second interlayer insulating layers ILD2, the remaining ones of the interlayer insulating layers ILD1 and ILD2 may have substantially the same thickness. However, the present invention is not limited to this example, and the thicknesses of the first and second interlayer insulating layers ILD1 and ILD2 may be variously changed, depending on technical properties required for each semiconductor device.

In an embodiment, the first and second interlayer insulating layers ILD1 and ILD2 may include at least one of silicon oxide, silicon nitride, silicon oxynitride, and/or low-k dielectric materials. For example, the first and second interlayer insulating layers ILD1 and ILD2 may be formed of or include high density plasma (HDP) oxide or tetraethyl orthosilicate (TEOS).

A source structure SC may be provided on the cell array region CAR and between the substrate 100 and the lowermost one of the first interlayer insulating layers ILD1. The source structure SC may correspond to the common source line CSL of FIG. 1 and the common source line 3205 of FIGS. 3 and 4. The source structure SC may include a first source conductive pattern SCP1 and a second source conductive pattern SCP2, which are sequentially stacked on the substrate 100. The second source conductive pattern SCP2 may be provided between the first source conductive pattern SCP1 and the lowermost one of the first interlayer insulating layers ILD1. A thickness of the first source conductive pattern SCP1 may be larger than a thickness of the second source conductive pattern SCP2. The first and second source conductive patterns SCP1 and SCP2 may include a semiconductor material (e.g., silicon) or a doped semiconductor material. In the case where the first and second source conductive patterns SCP1 and SCP2 include the doped semiconductor material, an impurity concentration of the first source conductive pattern SCP1 may be higher than an impurity concentration of the second source conductive pattern SCP2.

The first source conductive pattern SCP1 of the source structure SC may be provided on only the cell array region CAR, not on the contact region CCR. By contrast, the second source conductive pattern SCP2 of the source structure SC may be extended from the cell array region CAR to the contact region CCR. The second source conductive pattern SCP2 on the contact region CCR may be referred to as a second semiconductor layer 123.

A lower mold structure MSa may be provided on the contact region CCR and between the substrate 100 and the lowermost one of the first interlayer insulating layers ILD1. The lower mold structure MSa may include a first buffer insulating layer 111, a first semiconductor layer 121, a second buffer insulating layer 113, and the second semiconductor layer 123, which are sequentially stacked on the substrate 100.

The first semiconductor layer 121 may be provided between the substrate 100 and the second semiconductor layer 123. The first buffer insulating layer 111 may be provided between the substrate 100 and the first semiconductor layer 121, and the second buffer insulating layer 113 may be provided between the first semiconductor layer 121 and the second semiconductor layer 123. A bottom surface of the first buffer insulating layer 111 may be substantially coplanar with a bottom surface of the first source conductive pattern SCP1. A top surface of the second buffer insulating layer 113 may be substantially coplanar with a top surface of the first source conductive pattern SCP1.

In an embodiment, the first and second buffer insulating layers 111 and 113 may be formed of or include silicon oxide. For example, the first and second semiconductor layers 121 and 123 may be formed of or include a semiconductor material (e.g., silicon).

A plurality of vertical channel structures VS may be provided on the cell array region CAR to penetrate the stack ST and the source structure SC. The vertical channel structures VS may penetrate at least a portion of the substrate 100, a bottom surface of each of the vertical channel structures VS may be located at a level lower than a top surface of the substrate 100 and a bottom surface of the source structure SC. In other words, the vertical channel structures VS may be in direct contact with the substrate 100.

The vertical channel structures VS may be arranged in a zigzag shape in the first or second direction D1 or D2, when viewed in the plan view of FIG. 5. In an embodiment, the vertical channel structures VS may not be provided on the contact region CCR. The vertical channel structures VS may correspond to the vertical channel structures 3220 of FIGS. 2 to 4. The vertical channel structures VS may serve as the channel regions of the first transistors LT1 and LT2, the memory cell transistors MCT, and the second transistors UT1 and UT2 of FIG. 1.

The vertical channel structures VS may be provided in vertical channel holes CH, which are formed to penetrate the stack ST. Each of the vertical channel holes CH may include a first vertical channel hole CH1 penetrating the first stack ST1 and a second vertical channel hole CH2 penetrating the second stack ST2. The first vertical channel hole CH1 may further penetrate the source structure SC. In addition, the first vertical channel hole CH1 may further penetrate at least a portion of the substrate 100. The first and second vertical channel holes CH1 and CH2 of each of the vertical channel holes CH may be connected to each other in the third direction D3.

Each of the vertical channel structures VS may include a first portion VSa and a second portion VSb. The first portion VSa may be provided in the first vertical channel hole CH1, and the second portion VSb may be provided in the second vertical channel hole CH2. The second portion VSb may be provided on and connected to the first portion VSa.

Each of the vertical channel structures VS may include a data storage pattern DSP and a vertical semiconductor pattern VSP, which are sequentially provided on an inner side surface of each of the vertical channel holes CH, an insulating gapfill pattern VI, which fills an internal space defined by the vertical semiconductor pattern VSP, and a conductive pad PAD on the insulating gapfill pattern VI. The conductive pad PAD may be provided in an empty space, which is defined or enclosed by the insulating gapfill pattern VI and the data storage pattern DSP (or the vertical semiconductor pattern VSP). In detail, each of the vertical channel structures VS may include the insulating gapfill pattern VI, which fills an inner space of each of the vertical channel holes CH, and the data storage pattern DSP, which is interposed between an inner side surface of each of the vertical channel holes CH and the insulating gapfill pattern VI. In addition, each of the vertical channel structures VS may include the vertical semiconductor pattern VSP, which is interposed between the data storage pattern DSP and the insulating gapfill pattern VI. The conductive pad PAD may be disposed in the inner empty space of each vertical channel hole CH and on the insulating gapfill pattern VI. The vertical semiconductor pattern VSP may be extended in a region between the data storage pattern DSP and the conductive pad PAD.

Each of the vertical channel structures VS may have a circular, elliptical, or bar-shaped top surface. The data storage pattern DSP may enclose the vertical semiconductor pattern VSP. The vertical semiconductor pattern VSP may conformally cover an inner side surface of the data storage pattern DSP.

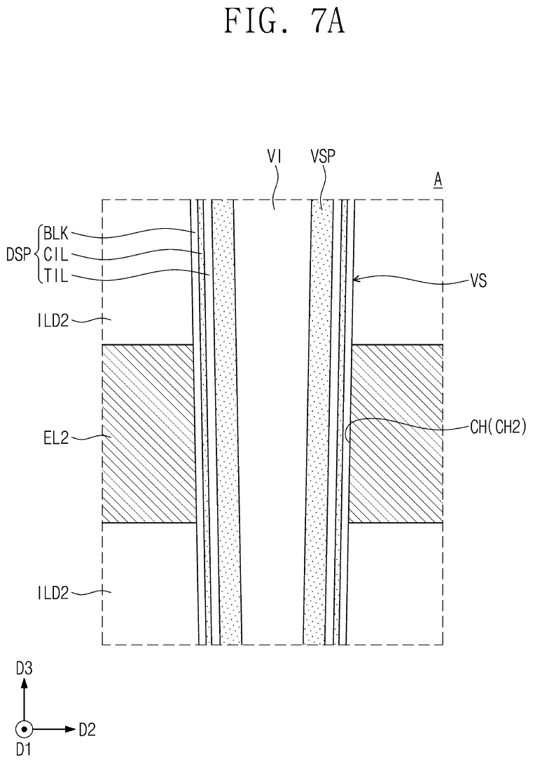

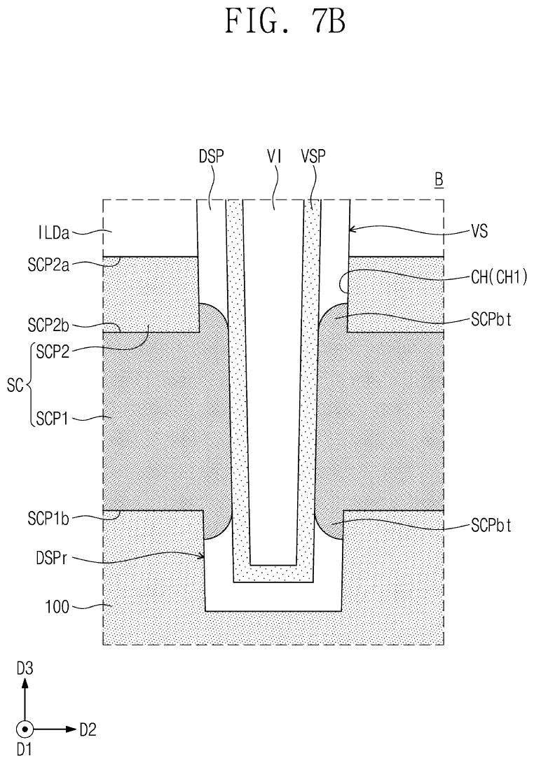

The vertical semiconductor pattern VSP may be formed of or include at least one of doped semiconductor materials and undoped or intrinsic semiconductor materials and may have a poly-crystalline or single-crystalline structure. As will be described with reference to FIG. 7B, the vertical semiconductor pattern VSP may be in contact with a portion of the source structure SC. The conductive pad PAD may be formed of or include at least one of doped semiconductor materials and conductive materials.

A plurality of dummy vertical channel structures DVS may be provided on the contact region CCR to penetrate a second insulating layer 170, the stack ST and the lower mold structure MSa. More specifically, the dummy vertical channel structures DVS may be provided to penetrate the pad portions ELp of the first and second gate electrodes EL1 and EL2. The dummy vertical channel structures DVS may be provided near cell contact plugs CCP to be described below. The dummy vertical channel structures DVS may not be provided on the cell array region CAR. The dummy vertical channel structures DVS and the vertical channel structures VS may be formed at the same time and may have substantially the same structure. However, in an embodiment, the dummy vertical channel structures DVS may be omitted, unlike the illustrated structure.

The second insulating layer 170 may be provided on the contact region CCR to cover the stack ST and a portion of the first insulating layer 30. More specifically, the second insulating layer 170 may cover the stepwise structure of the stack ST and may be provided on the pad portions ELp of the first and second gate electrodes EL1 and EL2. The second insulating layer 170 may have a substantially flat top surface. The top surface of the second insulating layer 170 may be substantially coplanar with the topmost surface of the stack ST. More specifically, the top surface of the second insulating layer 170 may be substantially coplanar with the top surface of the uppermost one of the second interlayer insulating layers ILD2 of the stack ST.

The second insulating layer 170 may include an insulating layer or a plurality of stacked insulating layers. The second insulating layer 170 may be formed of or include at least one of insulating materials (e.g., silicon oxide, silicon nitride, silicon oxynitride, and/or low-k dielectric materials). The second insulating layer 170 may include an insulating material that is different from the first and second interlayer insulating layers ILD1 and ILD2 of the stack ST. In the case where the first and second interlayer insulating layers ILD1 and ILD2 of the stack ST include high-density plasma oxide, the second insulating layer 170 may be formed of or include TEOS.

A third insulating layer 230 may be provided on the second insulating layer 170 and the stack ST. The third insulating layer 230 may cover the top surface of the second insulating layer 170, the top surface of the uppermost one of the second interlayer insulating layers ILD2 of the stack ST, and the top surfaces of the vertical channel structures VS and the dummy vertical channel structures DVS.

The third insulating layer 230 may include a single insulating layer or a plurality of stacked insulating layers. The third insulating layer 230 may be formed of or include at least one of silicon oxide, silicon nitride, silicon oxynitride, and/or low-k dielectric materials. The third insulating layer 230 may be formed of or include substantially the same insulating material as the second insulating layer 170 and may include an insulating material different from the first and second interlayer insulating layers ILD1 and ILD2 of the stack ST.

Bit line contact plugs BLCP may be provided to penetrate the third insulating layer 230 and may be connected to the vertical channel structures VS. The cell contact plugs CCP may be provided to penetrate the third insulating layer 230 and the second insulating layer 170 and may be connected to the first and second gate electrodes EL1 and EL2. Each of the cell contact plugs CCP may be provided to penetrate one of the first and second interlayer insulating layers ILD1 and ILD2 and may be in contact with one of the pad portions ELp of the first and second gate electrodes EL1 and EL2. Each of the cell contact plugs CCP may be adjacent a plurality of dummy vertical channel structures DVS but may be spaced apart from the dummy vertical channel structures DVS. The cell contact plugs CCP may correspond to the gate connection lines 3235 of FIG. 4.

A peripheral contact plug TCP may be provided to penetrate the third insulating layer 230, the second insulating layer 170, and at least a portion of a first insulating layer 30 and may be electrically connected to the peripheral circuit transistor PTR of the peripheral circuit structure PS. A plurality of the peripheral contact plugs TCP may be provided, unlike that illustrated in the drawings. The peripheral contact plug TCP may be spaced apart from the substrate 100, the source structure SC, and the stack ST in the first direction D1. The peripheral contact plug TCP may correspond to the penetration line 3245 of FIGS. 3 and 4.

The bit line contact plugs BLCP, the cell contact plugs CCP, and the peripheral contact plug TCP may have an increasing width in the first or second direction D1 or D2 as a vertical height in the third direction D3 increases.

The bit lines BL may be provided on the third insulating layer 230 and may be connected to the bit line contact plugs BLCP, respectively. The bit lines BL may correspond to the bit line BL of FIG. 1 and the bit lines 3240 of FIGS. 3 and 4.

First conductive lines CL1 connected to the cell contact plugs CCP and a second conductive line CL2 connected to the peripheral contact plug TCP may be provided on the third insulating layer 230. The first and second conductive lines CL1 and CL2 may correspond to the conductive lines 3250 of FIG. 4.

The bit line contact plugs BLCP, the cell contact plugs CCP, the peripheral contact plug TCP, the bit lines BL, and the first and second conductive lines CL1 and CL2 may be formed of or include at least one of conductive materials (e.g., metallic materials). Although not shown, the bit lines BL as well as additional interconnection lines and additional vias, which are electrically connected to the first and second conductive lines CL1 and CL2, may be further provided on the third insulating layer 230.

In the case where a plurality of stacks ST are provided, a separation structure 160 may be provided in a second trench TR2, which is formed between the stacks ST and is extended in the first direction D1. The second trench TR2 may not be extended to a region on the contact region CCR of the peripheral substrate 10. The separation structure 160 may be spaced apart from the vertical channel structures VS and the dummy vertical channel structures DVS in the second direction D2. In an embodiment, a top surface of the separation structure 160 may be located at a level higher than the top surfaces of the vertical channel structures VS and the dummy vertical channel structures DVS. A bottom surface of the separation structure 160 may be substantially coplanar with the top surface of the first source conductive pattern SCP1 and may be located at a level higher than the top surface of the substrate 100.

In an embodiment, a plurality of separation structures 160 may be provided, and in this case, the separation structures 160 may be spaced apart from each other in the second direction D2 with the stack ST interposed therebetween. The separation structures 160 may correspond to the separation structures 3230 of FIG. 4.

A separation spacer 130 may be provided between the separation structure 160 and the stack ST to enclose the separation structure 160. The separation spacer 130 may conformally cover side surfaces of the first and second interlayer insulating layers ILD1 and ILD2 and the first and second gate electrodes EL1 and EL2. In an embodiment, the separation structure 160 may be formed of or include silicon oxide. The separation spacer 130 may be formed of or include a material having an etch selectivity with respect to the second source conductive pattern SCP2, the first and second semiconductor layers 121 and 123. The separation spacer 130 may be formed of or include, for example, silicon nitride.

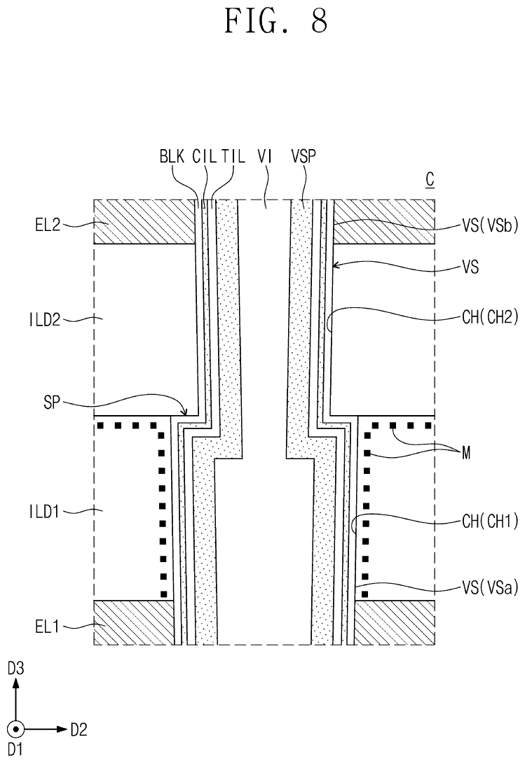

FIGS. 7A and 7B are enlarged sectional views illustrating portions ‘A’ and ‘B’ of FIG. 6A. FIG. 8 is an enlarged sectional view illustrating a portions ‘C’ of FIG. 6A. For concise description, a previously described element may be identified by the same reference number without repeating an overlapping description thereof.

FIGS. 7A and 7B illustrate the source structure SC, which includes the first and second source conductive patterns SCP1 and SCP2, and one of the vertical channel structures VS, each of which includes the data storage pattern DSP, the vertical semiconductor pattern VSP, the insulating gapfill pattern VI, and a lower data storage pattern DSPr. For convenience in description, one of the stacks ST and one of the vertical channel structures VS will be described below, but the remaining ones of the stacks ST and the remaining ones of the vertical channel structures VS may be provided to have substantially the same features.

The data storage pattern DSP may include a blocking insulating layer BLK, a charge storing layer CIL, and a tunneling insulating layer TIL, which are sequentially stacked. The blocking insulating layer BLK may be adjacent to the stack ST or the source structure SC, and the tunneling insulating layer TIL may be adjacent to the vertical semiconductor pattern VSP. The charge storing layer CIL may be interposed between the blocking insulating layer BLK and the tunneling insulating layer TIL. The blocking insulating layer BLK may conformally cover the inner side surface of each of the vertical channel holes CH. The charge storing layer CIL may conformally cover an inner side surface of the blocking insulating layer BLK. The charge storing layer CIL may be spaced apart from each of the first interlayer insulating layers ILD1 and each of the second interlayer insulating layers ILD2 and each of the first gate electrodes EL1 and each of the second gate electrodes EL2 with the blocking insulating layer BLK interposed therebetween. The tunneling insulating layer TIL may conformally cover an inner side surface of the charge storing layer CIL. The charge storing layer CIL may be interposed between the blocking insulating layer BLK and the tunneling insulating layer TIL.

The blocking insulating layer BLK, the charge storing layer CIL, and the tunneling insulating layer TIL may be extended in the third direction D3. In an embodiment, the Fowler-Nordheim (FN) tunneling phenomenon, which is caused by a voltage difference between the vertical semiconductor pattern VSP and the first and second gate electrodes EL1 and EL2, may be used to store and change data in the data storage pattern DSP. For example, the blocking insulating layer BLK and the tunneling insulating layer TIL may include silicon oxide, and the charge storing layer CIL may include silicon nitride or silicon oxynitride.

The first source conductive pattern SCP1 of the source structure SC may be in contact with the vertical semiconductor pattern VSP, and the second source conductive pattern SCP2 may be spaced apart from the vertical semiconductor pattern VSP, with the data storage pattern DSP interposed therebetween. The first source conductive pattern SCP1 may be spaced apart from the insulating gapfill pattern VI, with the vertical semiconductor pattern VSP interposed therebetween.

More specifically, the first source conductive pattern SCP1 may include protruding portions SCPbt, which are respectively located at a level higher than a bottom surface SCP2b of the second source conductive pattern SCP2 or at a level lower than a bottom surface SCP1b of the first source conductive pattern SCP1. A surface of the protruding portions SCPbt, which is in contact with the data storage pattern DSP or the lower data storage pattern DSPr, may have a curved shape.

Even not shown in FIG. 7B, each of the data storage pattern DSP and the lower data storage pattern DSPr may also include the blocking insulating layer BLK, the charge storing layer CIL, and the tunneling insulating layer TIL, which are sequentially stacked as shown in FIG. 7A.

Referring to FIG. 8, the first and second portions VSa and VSb of the vertical channel structure VS may have an increasing width in the first or second direction D1 or D2 as a vertical height in the third direction D3 increases. The uppermost width of the first portion VSa may be larger than the lowermost width of the second portion VSb. For example, a side surface of each of the vertical channel structures VS may have a stepwise surface SP, at an interface between the first and second portions VSa and VSb. For example, the side surface of each of the vertical channel structures VS may have the stepwise surface SP, at a boundary between the first and second stacks ST1 and ST2. The stepwise surface SP may be a top surface of the first portion VSa exposed by the second portion VSb. The stepwise surface SP may connect a side surface of the first portion VSa to a side surface of the second portion VSb, at a boundary between the first and second portions VSa and VSb. The stepwise surface SP may be located at the same level as the boundary between the first and second portions VSa and VSb. The stepwise surface SP may be located at the same level as the boundary between the first and second stacks ST1 and ST2. Due to the stepwise surface SP, a width of the vertical channel structure VS may be abruptly changed at the boundary between the first and second portions VSa and VSb. However, the present invention is not limited to this example, and the side surface of each of the vertical channel structures VS may have two or more stepwise surfaces at different levels.

The uppermost one of the first interlayer insulating layers ILD1 may include a metalloid element M, which is contained in a reduction gas that is used when an active layer AL will be formed in a region adjacent to the vertical channel structures VS. As an example, in the case where the reduction gas is B₂H₆, the metalloid element may be boron (B). In addition, the first portion VSa of each of the vertical channel structures VS may have a height measured from a bottom surface of the first portion VSa in the third direction D3. The first interlayer insulating layers ILD1, which are located at a level higher than half the total height of the first portion VSa may include the metalloid element M in the region adjacent to the vertical channel structures VS. In addition, a top surface of the uppermost one of the first interlayer insulating layers ILD1 may include the metalloid element M. For example, the uppermost one of the first interlayer insulating layers ILD1 may include boron (B) on the top surface thereof and on a side surface adjacent to the vertical channel structure VS.

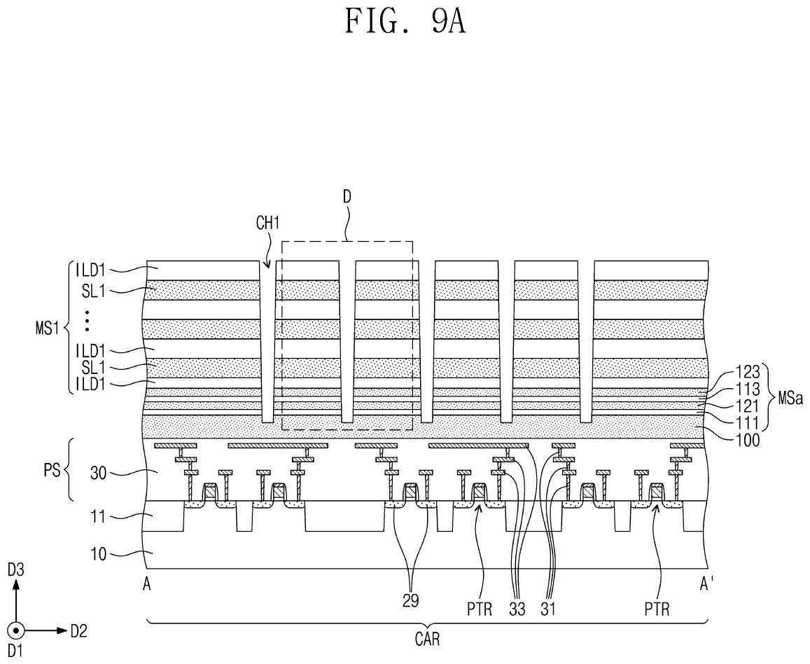

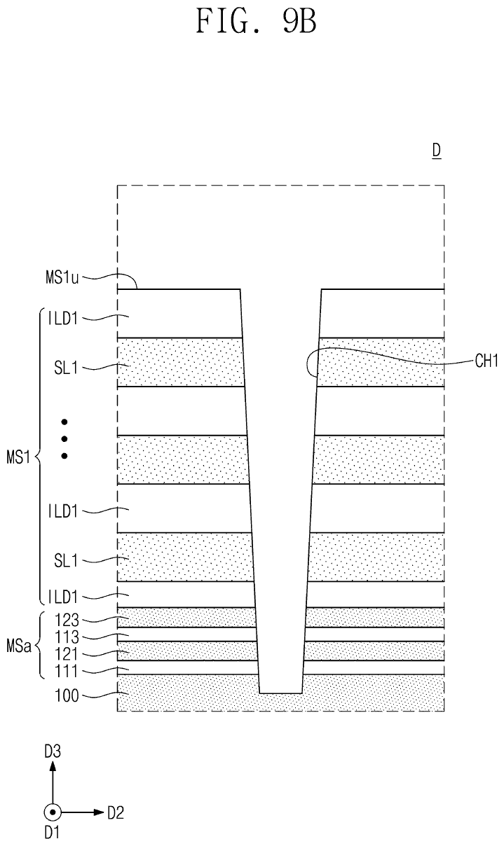

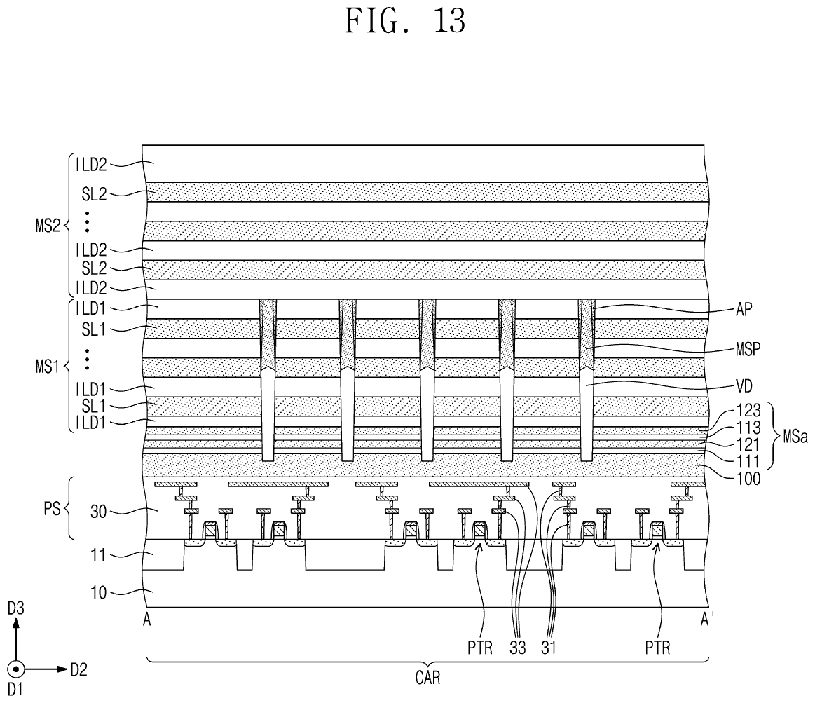

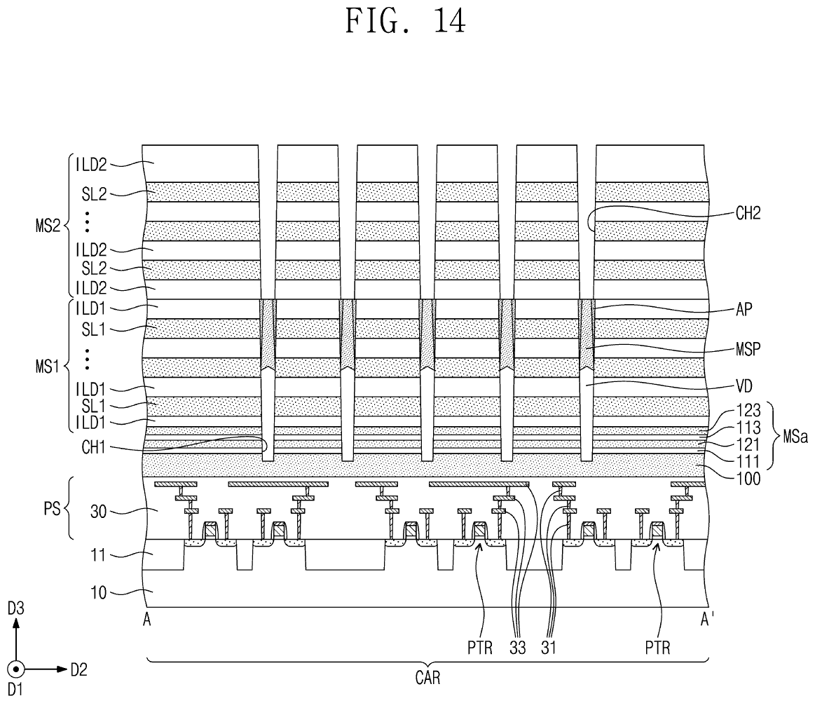

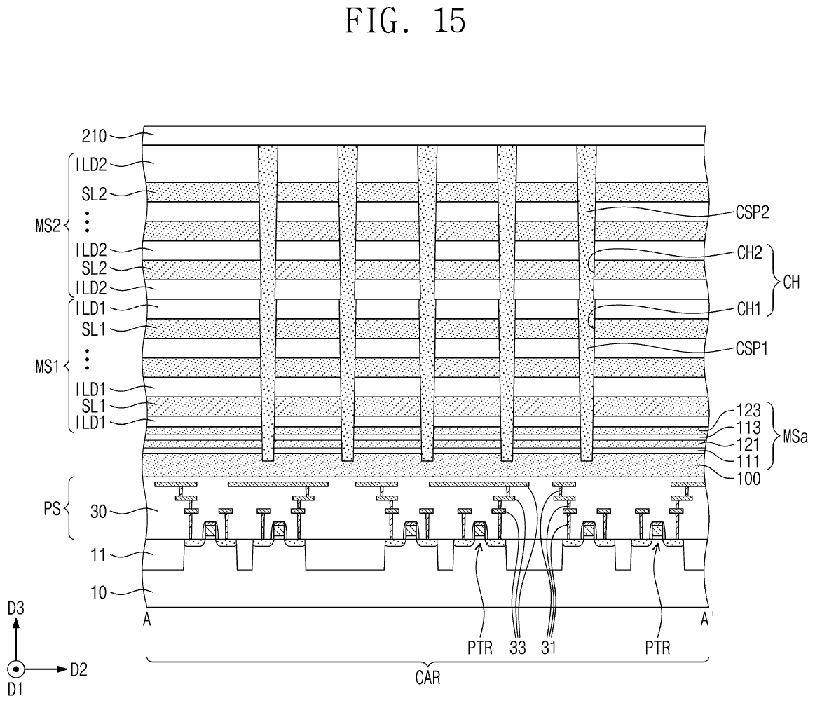

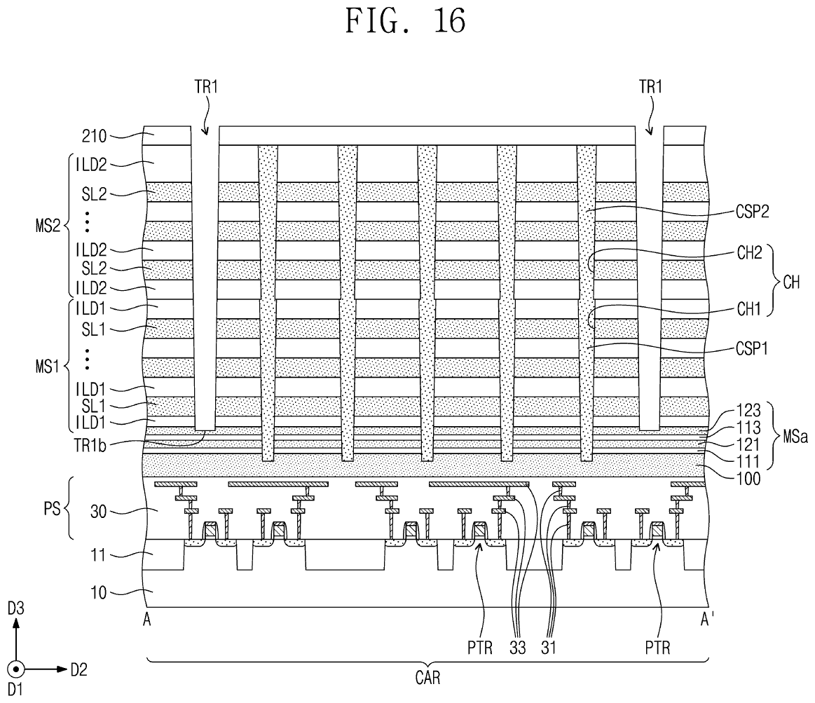

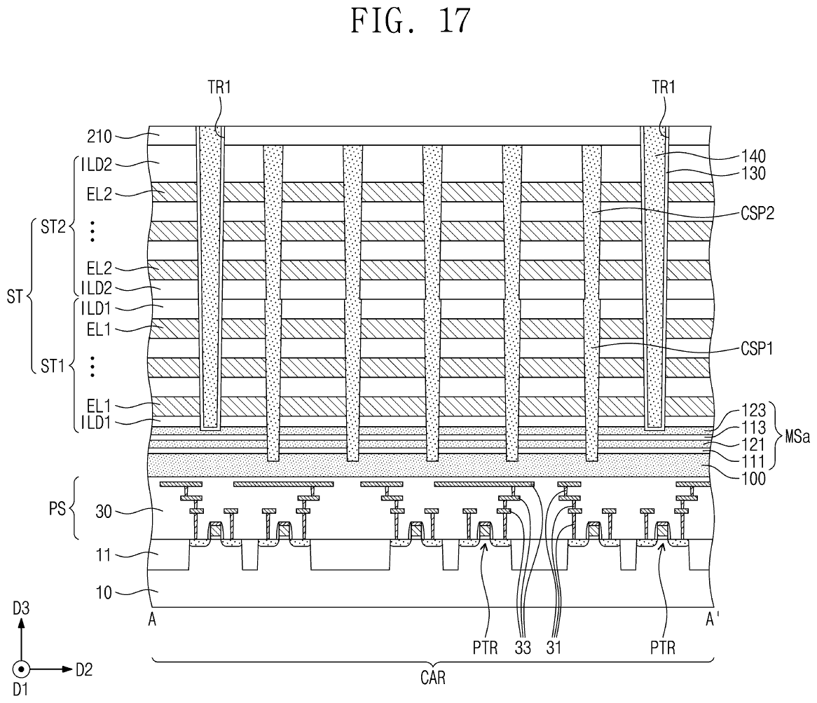

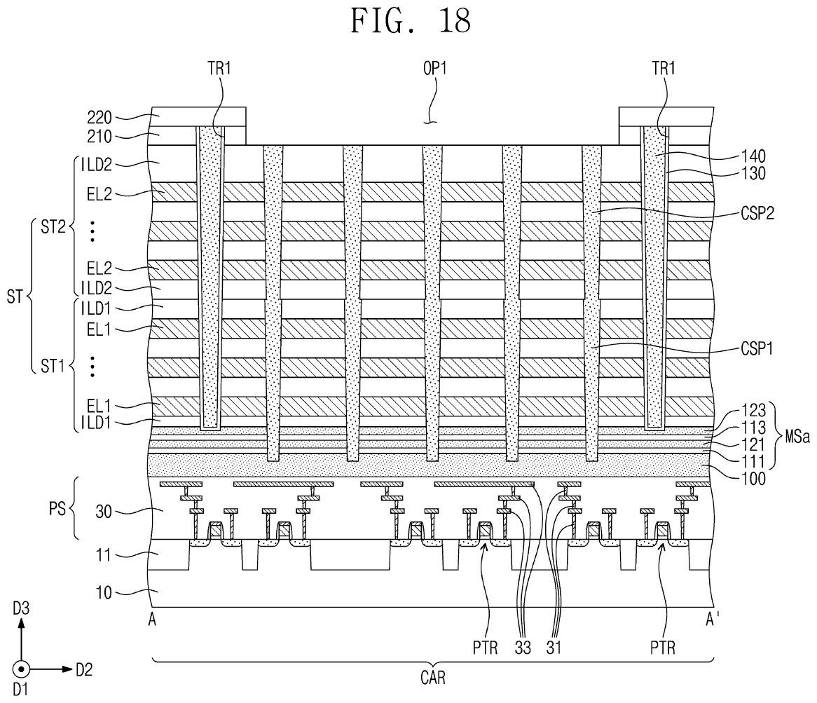

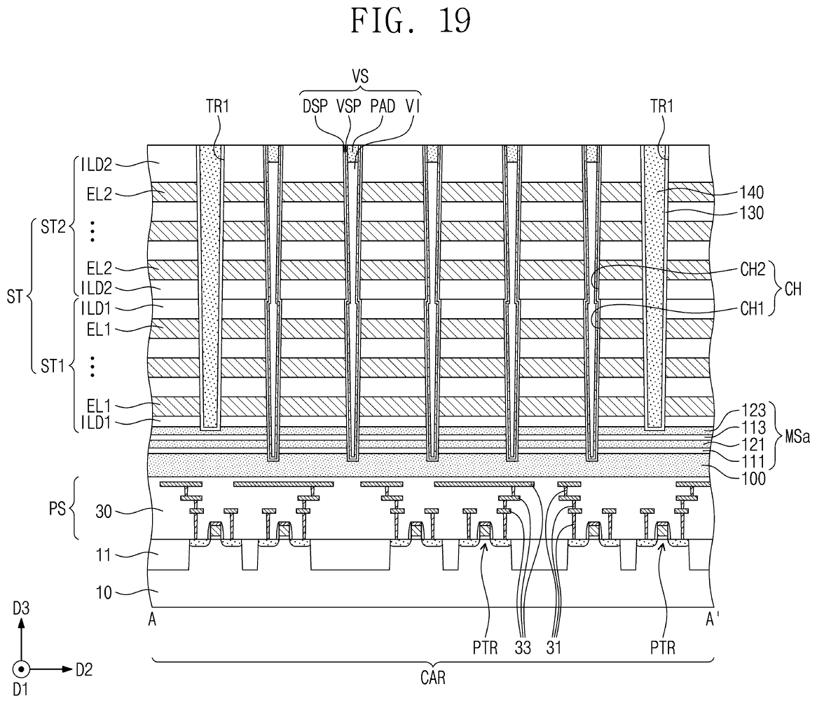

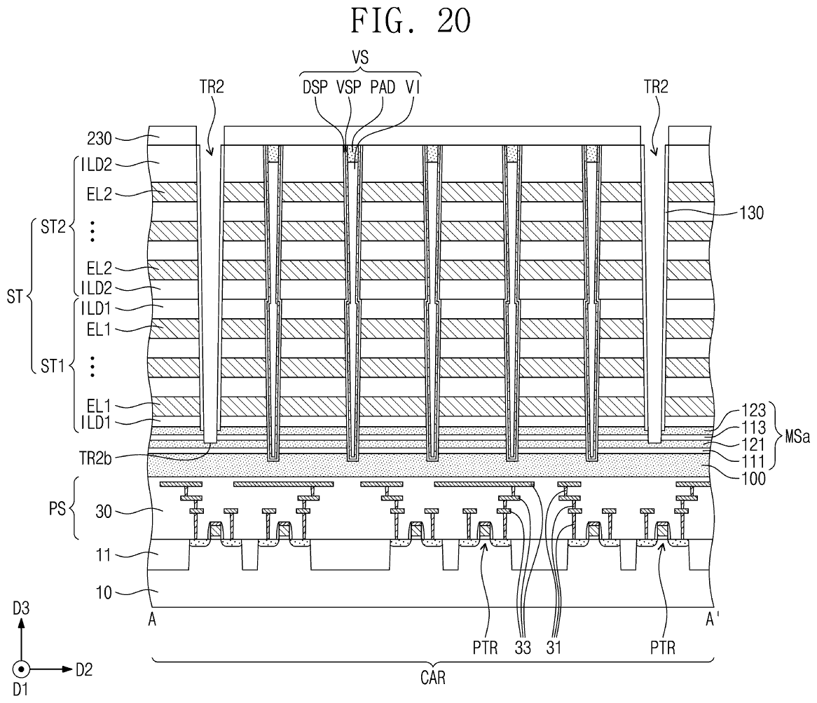

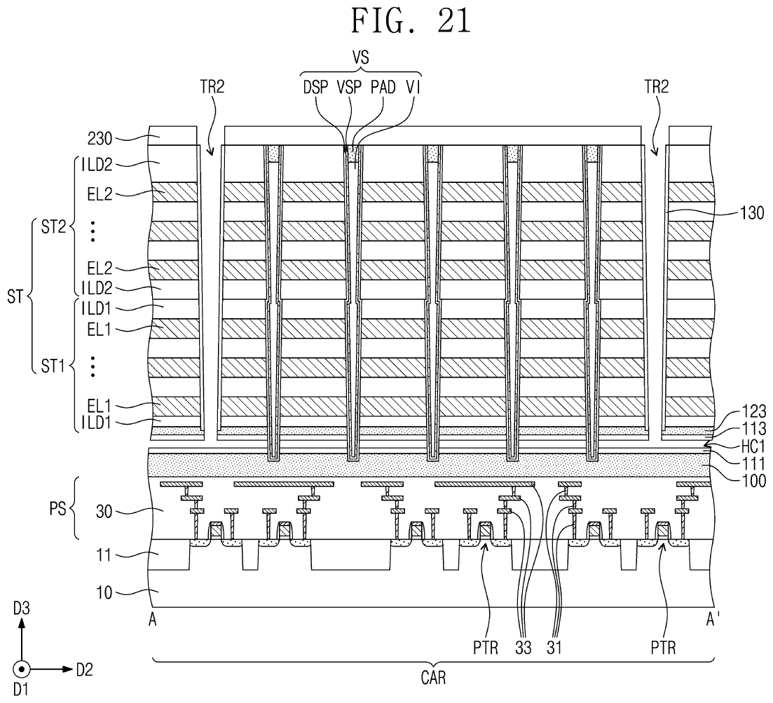

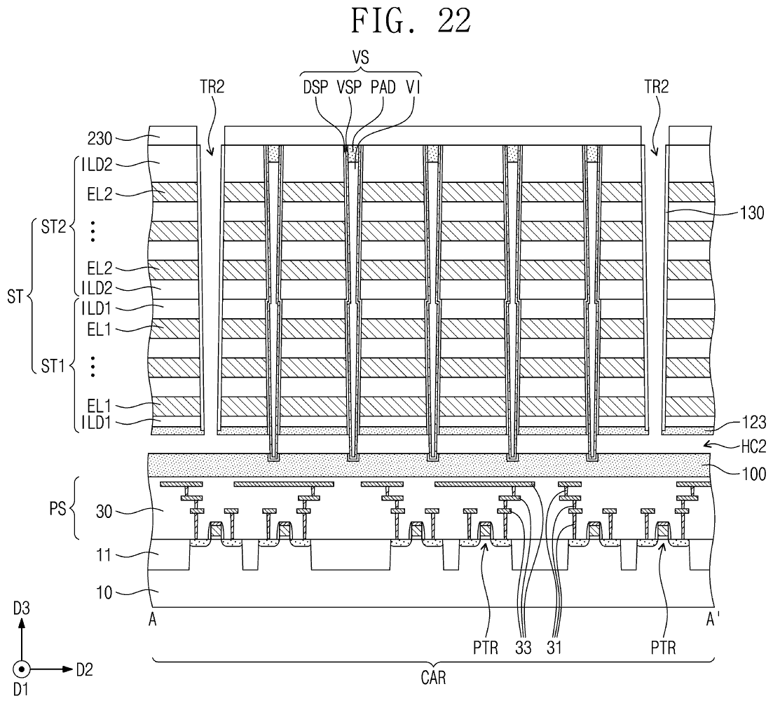

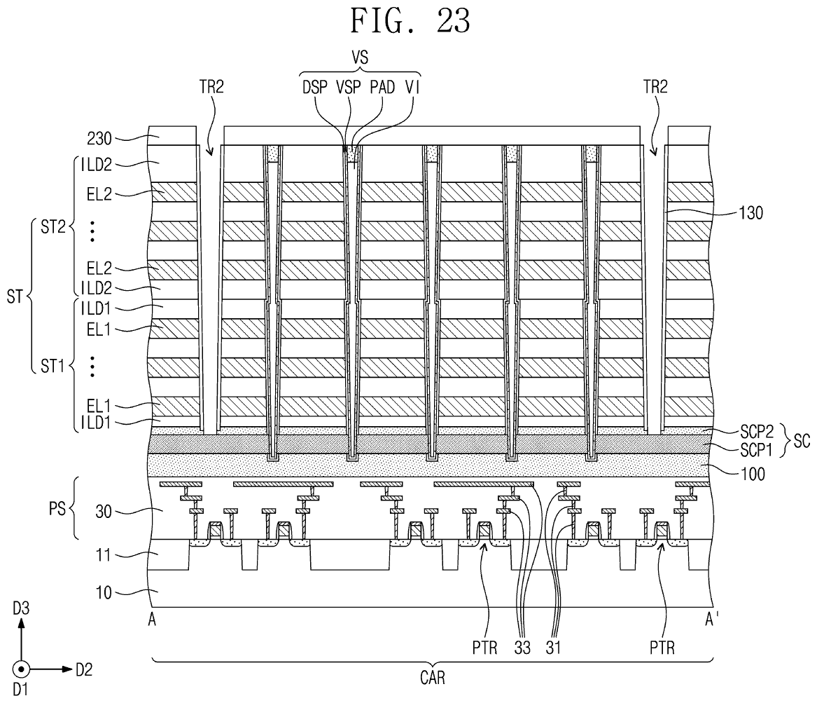

FIGS. 9A, 9B, 10A to 10D, 11A to 11H, 12A to 12D, and 13 to 23 are sectional views illustrating a method of fabricating a semiconductor device, according to an embodiment of the inventive concept. In detail, FIGS. 9A and 13 to 23 are sectional views taken along a line A-A′ of FIG. 5. FIGS. 9B and 10A to 10D, 11A to 11H, 12A to 12D are enlarged sectional views corresponding to a portion ‘D’ of FIG. 9A. Hereinafter, the fabrication method according to an embodiment of the inventive concept will be described in more detail with reference to FIGS. 5, 6A, 6B, and 9A, 9B, 10A to 10D, 11A to 11H, 12A to 12D, and 13 to 23.

Referring to FIGS. 5, 9A, and 9B, the peripheral substrate 10 including the cell array region CAR and the contact region CCR may be provided. The device isolation layer 11 may be formed in the peripheral substrate 10 to define an active region. The device isolation layer 11 may include forming a trench in an upper portion of the peripheral substrate 10 and filling the trench with a silicon oxide layer.

The peripheral circuit transistors PTR may be formed on the active region defined by the device isolation layer 11. The peripheral contact plugs 31 and the peripheral circuit interconnection lines 33 may be formed to be connected to the peripheral source/drain regions 29 of the peripheral circuit transistors PTR. The first insulating layer 30 may be formed to cover the peripheral circuit transistors PTR, the peripheral contact plugs 31, and the peripheral circuit interconnection lines 33.

The substrate 100 may be formed on the first insulating layer 30. The substrate 100 may be extended from the cell array region CAR toward the contact region CCR.

A portion of the substrate 100 on the contact region CCR may be removed. The partial removal of the substrate 100 may include forming a mask pattern to cover a portion of the contact region CCR and the cell array region CAR and etching the substrate 100 using the mask pattern as an etching mask. The partial removal of the substrate 100 may be performed to form a region, in which the peripheral contact plug TCP described above will be provided.

The lower mold structure MSa may be formed on the substrate 100. The formation of the lower mold structure MSa may include sequentially stacking the first buffer insulating layer 111, the first semiconductor layer 121, the second buffer insulating layer 113, and the second semiconductor layer 123 on the substrate 100. The first and second buffer insulating layers 111 and 113 may be formed of or include, for example, silicon oxide. The first and second semiconductor layers 121 and 123 may be formed of or include a semiconductor material (e.g., silicon).

A first mold structure MS1 may be formed on the lower mold structure MSa. In an embodiment, the formation of the first mold structure MS1 may include alternately stacking the first interlayer insulating layers ILD1 and first sacrificial layers SL1 on the substrate 100. The first sacrificial layers SL1 may include a material different from the first interlayer insulating layers ILD1. The first sacrificial layers SL1 may include a material having an etch selectivity with respect to the first interlayer insulating layers ILD1. For example, the first sacrificial layers SL1 may include silicon nitride, and the first interlayer insulating layers ILD1 may include silicon oxide. The first sacrificial layers SL1 may be formed to have substantially the same thickness, and the first interlayer insulating layers ILD1 may have at least two different thicknesses depending on their vertical positions. As an example, the lowermost one of the first interlayer insulating layers ILD1 may be thinner than the others of the first interlayer insulating layers ILD1.

The first vertical channel holes CH1 may be formed to penetrate the first mold structure MS1 and the lower mold structure MSa. In an embodiment, the first vertical channel holes CH1 may be formed to penetrate a portion of the substrate 100. A bottom surface of each of the first vertical channel holes CH1 may be located in the substrate 100. In an embodiment, the formation of the first vertical channel holes CH1 may include forming a mask pattern (not shown) on the first mold structure MS1 and sequentially etching the first mold structure MS1, the lower mold structure MSa, and a portion of the substrate 100 using the mask pattern as an etch mask. The etching step may be performed using an anisotropic etching process. A width of each of the first vertical channel holes CH1 in the first or second direction D1 or D2 may increase as a distance from the substrate 100 increases (i.e., in the third direction D3).

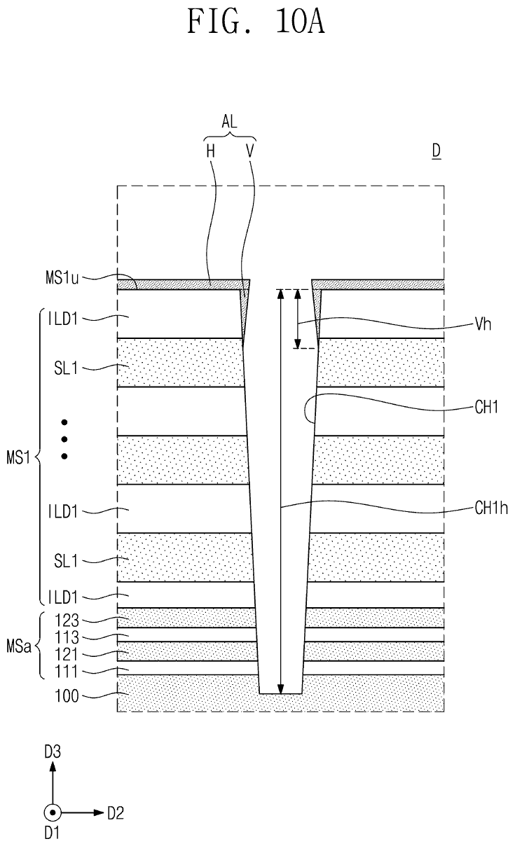

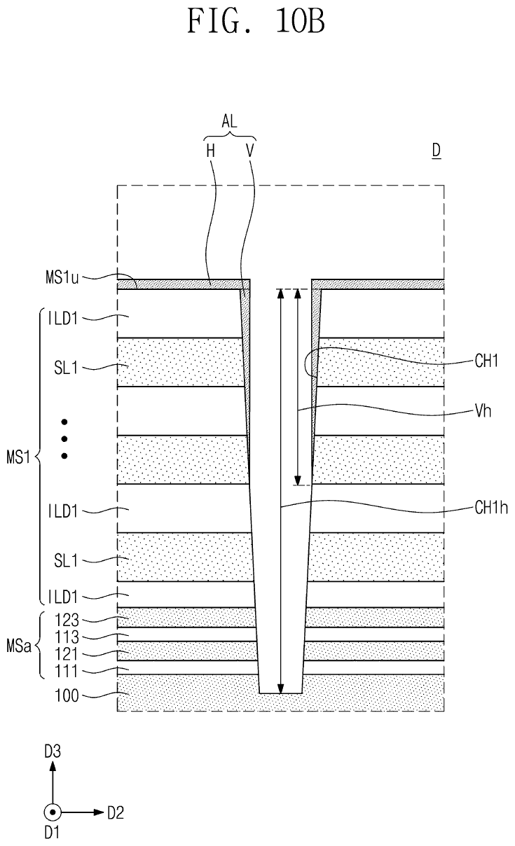

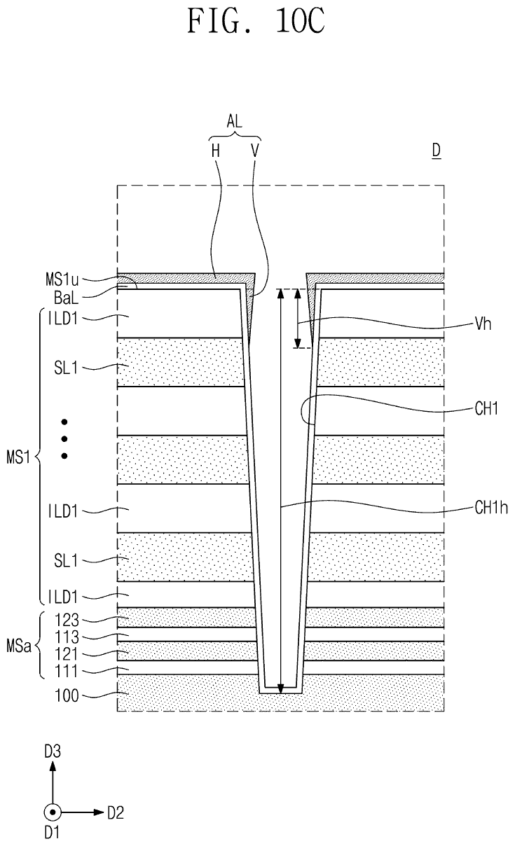

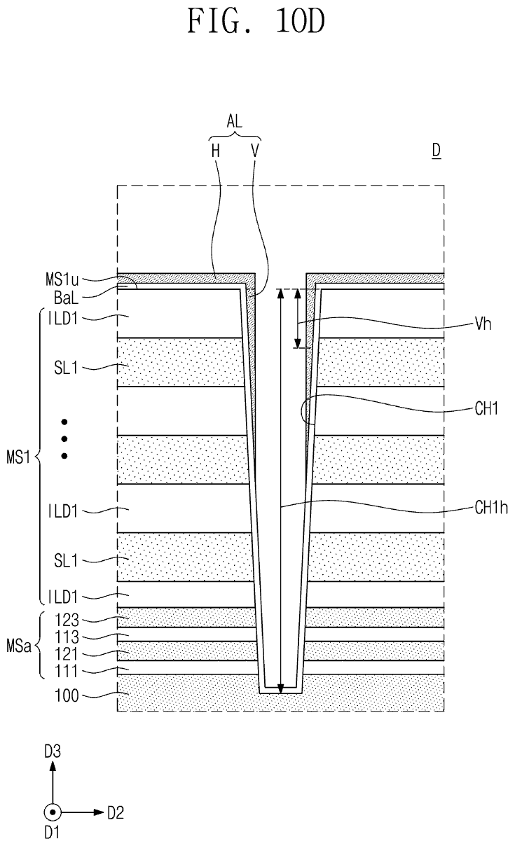

Referring to FIGS. 10A and 10B, the active layer AL may be formed on the first mold structure MS1. In detail, the active layer AL may cover a top surface MS1u of the first mold structure MS1 and may be extended to cover an upper side surface of each of the first vertical channel holes CH1. The active layer AL may include a horizontal portion H covering the top surface MS1u of the first mold structure MS1 and a vertical portion V covering the upper side surface of each of the first vertical channel holes CH1. For example, the vertical portion V may be a portion of the active layer AL, which is horizontally overlapped with the first mold structure MS1, and the horizontal portion H may be a remaining portion of the active layer AL, excluding the vertical portion V. A width of the vertical portion V in the horizontal direction D1 or D2 may increase as a distance from the substrate 100 increases (i.e., in the third direction D3). The active layer AL may be a metal layer containing a metalloid element.

In an embodiment, the active layer AL may be formed using a deposition method (e.g., a chemical vapor deposition (CVD) method or an atomic layer deposition (ALD) method). As an example, the active layer AL may be formed through a chemical reaction, in which a precursor and a reduction gas are used. In an embodiment, WF₆ may be used as the precursor, and at least one of H₂, SiH₄, and B₂H₆ may be used as the reduction gas. In an embodiment, the active layer AL may be formed by an atomic layer deposition (ALD) method, in which WF₆ and B₂H₆ are used as the precursor and the reduction gas, respectively. In this case, the active layer AL may be a boron-rich tungsten (W) layer. Thus, a metalloid element (e.g., boron (B)) may infiltrate a region of the first mold structure MS1 covered with the active layer AL. For example, at least a portion of the first interlayer insulating layers ILD1 may contain the metalloid element (e.g., boron (B)).

Each of the first vertical channel holes CH1 may have a hole length CH1h in the third direction D3. The vertical portion V of the active layer AL may have a vertical length Vh in the third direction D3. For example, the hole length CH1h of each of the first vertical channel holes CH1 may be a distance from the top surface MS1u of the first mold structure MS1 to a bottom surface of each of the first vertical channel holes CH1, measured in the third direction D3 or an opposite direction thereof. The vertical length Vh of the vertical portion V may be a distance from the top surface MS1u of the first mold structure MS1 to the bottommost portion of the vertical portion V, measured in the third direction D3 or an opposite direction thereof. The vertical length Vh may be smaller than the hole length CH1h. As an example, referring to FIG. 10A, the vertical length Vh may be smaller than half the hole length CH1h. As another example, referring to FIG. 10B, the vertical length Vh may be about half the hole length CH1h. For example, the vertical length Vh may be 15% to 50% of the hole length CH1h. In an embodiment, the vertical length Vh may be 55% to 60% of the hole length CH1h. The vertical portion V may be formed to cover at least a side surface of the uppermost one of the first interlayer insulating layer ILD1. The vertical length Vh may be controlled by adjusting the injection time of the reduction gas in the afore-described step of forming the active layer AL. In the case where the injection time of the reduction gas is adjusted in unit of 0.1 second increments, the vertical length Vh may be controlled in 10 nm increments. For example, if the injection time of the reduction gas is increased or decreased by 0.1 seconds, the vertical length Vh may be increased or decreased by 10 nm.

Referring to FIGS. 10C and 10D, a barrier layer Ba may be formed after the formation of the first vertical channel holes CH1 and before the formation of the active layer AL. The barrier layer Ba may conformally cover side and bottom surfaces of each of the first vertical channel holes CH1 and may be extended to a region on the top surface MS1u of the first mold structure MS1. In an embodiment, the barrier layer Ba may be formed of or include at least one of metal and metal nitride materials (e.g., Ti, TiN, Ta, and TaN).

The barrier layer Ba may be used to protect the first mold structure MS1. In detail, in the case where a precursor, which is supplied to form the active layer AL, reacts with the first mold structure MS1, a lifting issue may occur. By forming the barrier layer Ba, it may be possible to prevent the lifting issue from occurring in a subsequent process of forming the active layer AL.

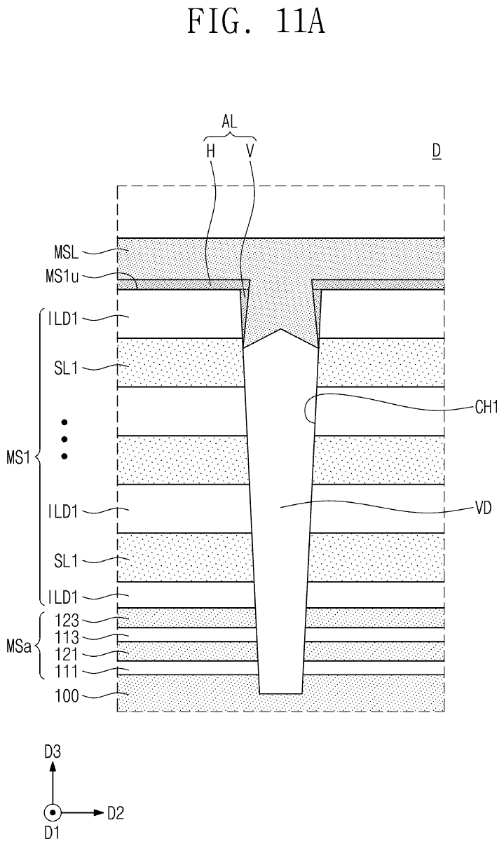

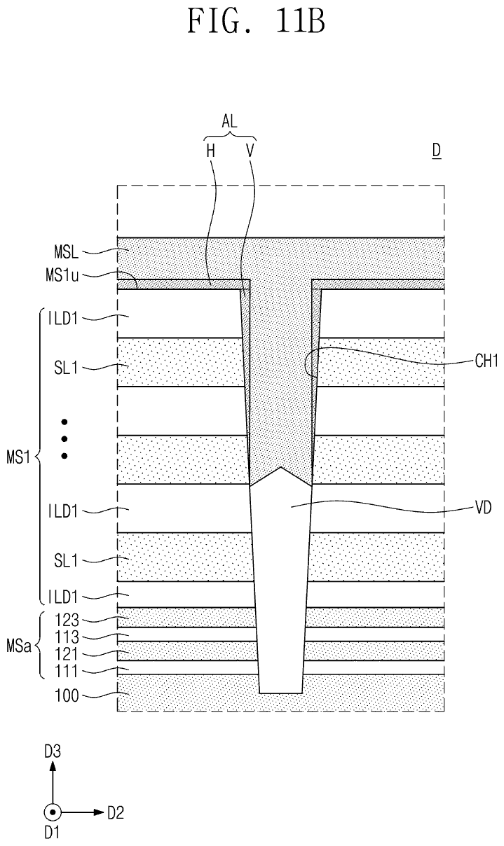

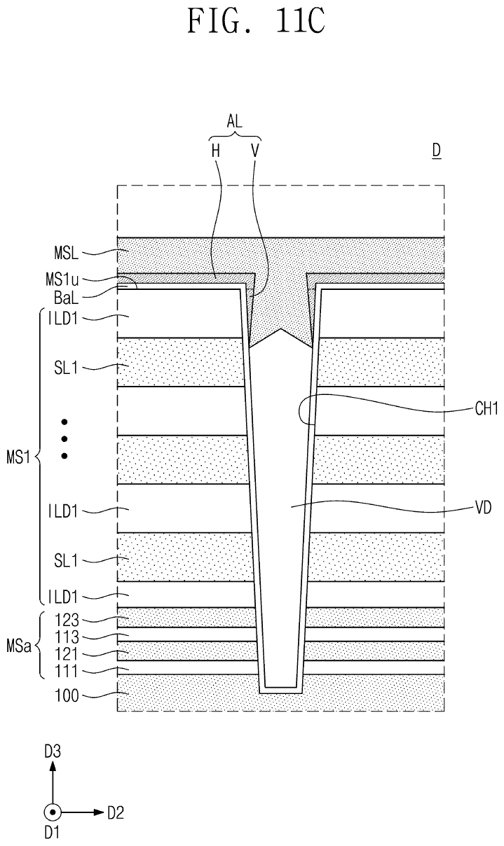

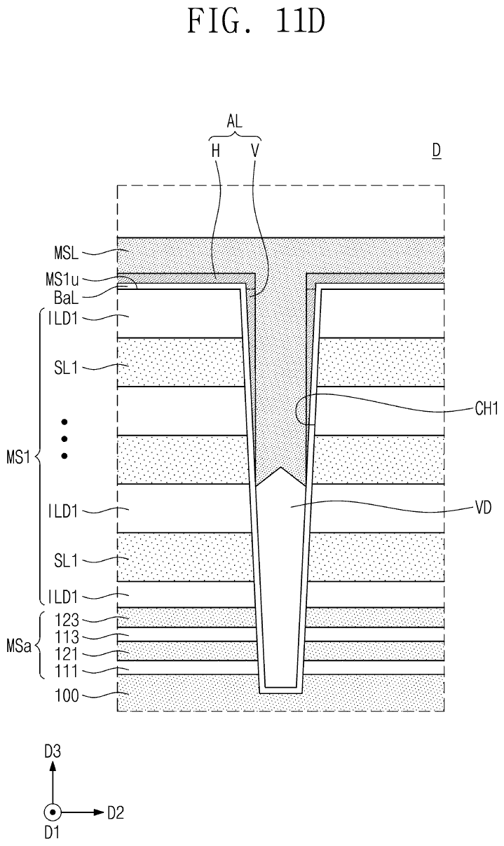

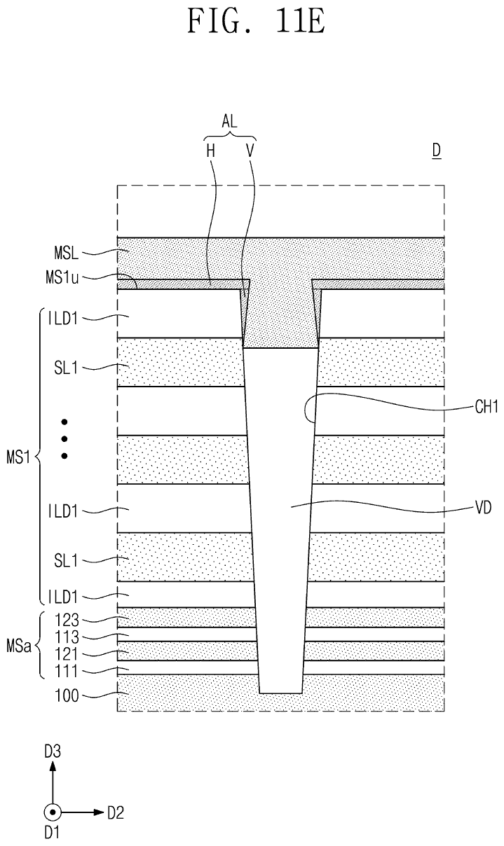

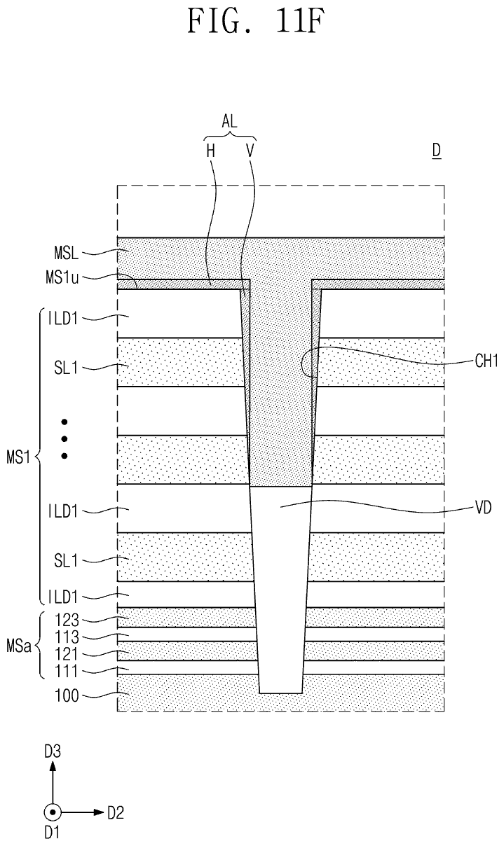

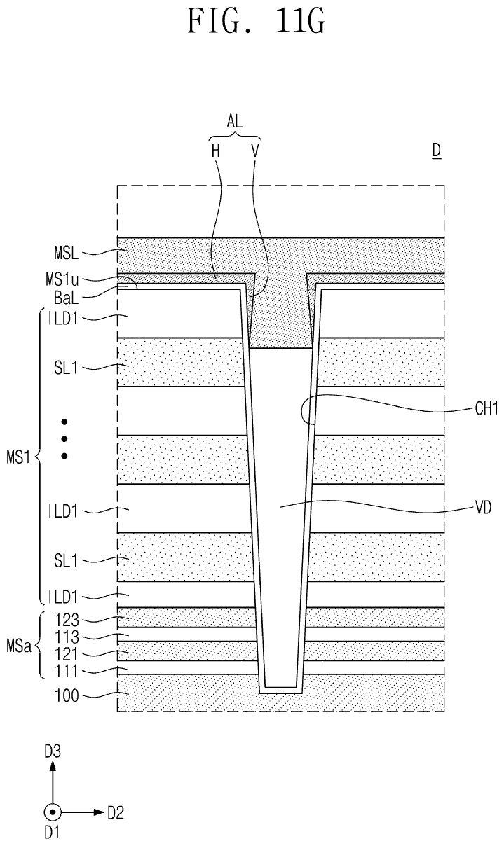

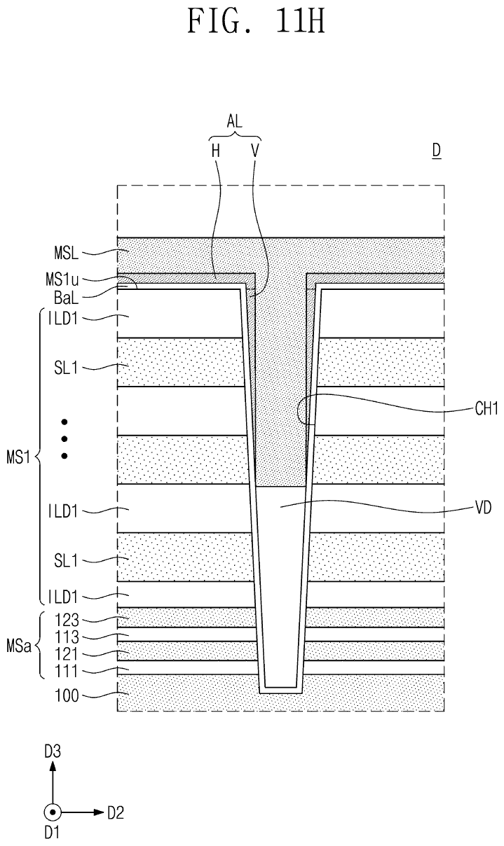

Referring to FIGS. 11A to 11D, a mold sacrificial layer MSL may be formed on the active layer AL to fill an upper portion of each of the first vertical channel holes CH1. Thus, a void VD may be formed in a remaining portion of each of the first vertical channel holes CH1. In an embodiment, the mold sacrificial layer MSL may be formed through a chemical reaction, in which a precursor and a reduction gas are used. In an embodiment, WF₆ may be used as the precursor for forming the mold sacrificial layer MSL, and H₂ may be used as the reduction gas. This may be because, if the hydrogen H₂, which causes a relatively slow reaction, is used for the chemical reaction, it is possible to form a bulk tungsten (W) layer with a good step coverage property. The mold sacrificial layer MSL may not be formed on a side surface of each of the first vertical channel holes CH1, which are not covered with the active layer AL.

The void VD may be placed in the first vertical channel hole CH1. The void VD may be a remaining portion of the first vertical channel hole CH1, which is not filled with the active layer AL and the mold sacrificial layer MSL. As an example, referring to FIGS. 11A and 11C, a volume of the void VD may be smaller than half a volume of the first vertical channel hole CH1. As another example, referring to FIGS. 11B and 11D, the volume of the void VD may be about half the volume of the first vertical channel hole CH1. For example, the volume of the void VD may be 15% to 50% of the volume of the first vertical channel hole CH1. In an embodiment, the volume of the void VD may be 55% to 60% of the volume of the first vertical channel hole CH1.

The materials for the active layer AL and the mold sacrificial layer MSL are not limited to the above examples. As an example, the active layer AL may be formed of or include a material containing a metal, which is contained in the mold sacrificial layer MSL. In this case, the mold sacrificial layer MSL may not be formed on the side surface of the first vertical channel hole CH1, which is not covered with the active layer AL, and may be locally formed on the active layer AL. As a result, the void VD may be formed on the side surface of the first vertical channel hole CH1, which is not covered with the active layer AL. For example, by adjusting a region covered with the active layer AL, it may be possible to control the void VD to a desired size.

In an embodiment, as shown in FIGS. 11A to 11D, an upper portion of the void VD may have a cone shape. For example, a bottom surface of the mold sacrificial layer MSL, which is located in the first vertical channel hole CH1, may have a cone shape, not a flat shape. In another embodiment, as shown in FIGS. 11E to 11H, the upper portion of the void VD may have a flat shape. However, in the present invention, the shape of the void VD is not limited to these examples.

According to an embodiment of the inventive concept, after the formation of the first vertical channel holes CH1, the void VD may be intentionally formed in each of the first vertical channel holes CH1. For example, since the first vertical channel holes CH1 are not fully filled, it may be possible to prevent a crack or warpage issue from occurring in the first mold structure MS1 by a stress. This may make it possible to easily form a second mold structure MS2 in a subsequent process and to improve the electrical and reliability characteristics of the fabricated semiconductor device. In addition, since the crack or warpage issue in the first mold structure MS1 is prevented, the yield may be increased. Furthermore, by adjusting the size of the void VD, it may be possible to prevent an etchant from being unintentionally supplied into the first vertical channel holes CH1 in a subsequent process.

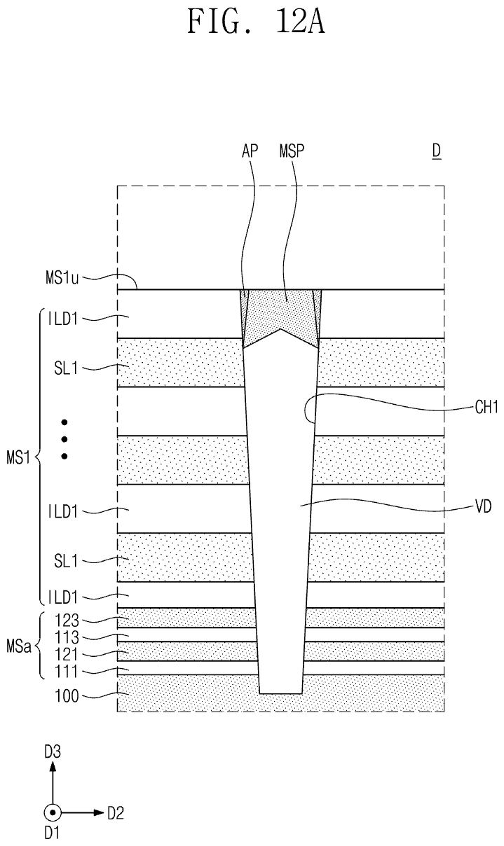

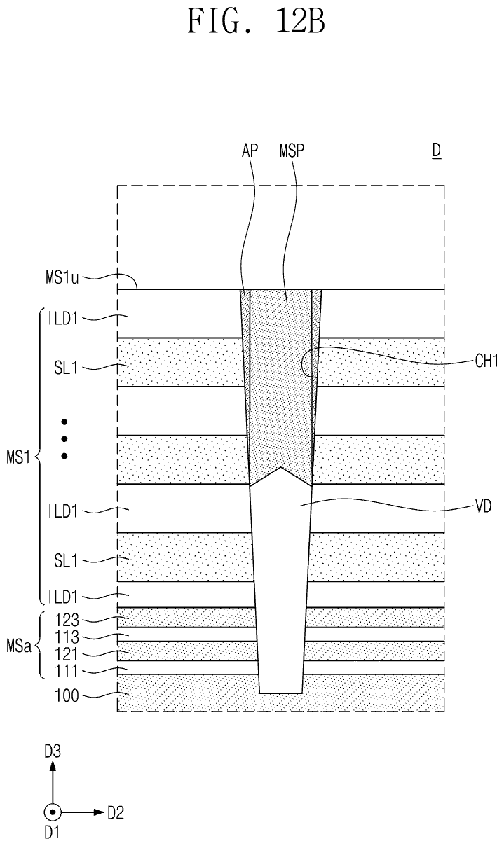

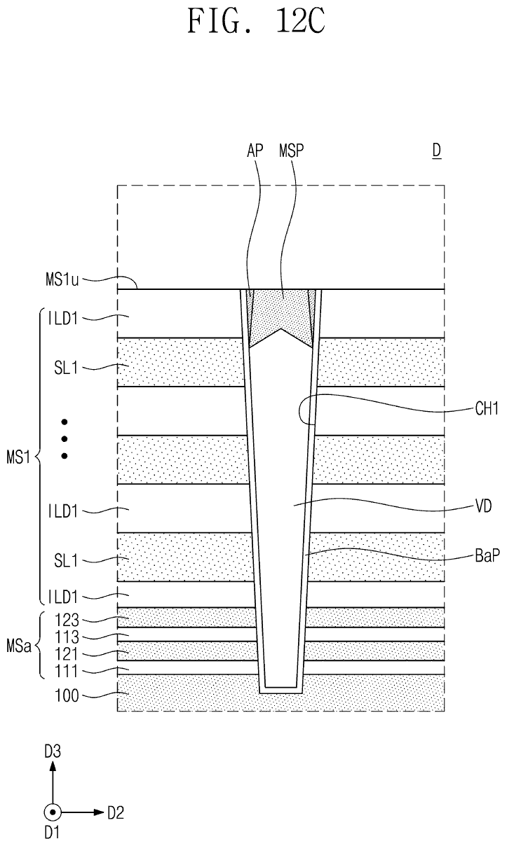

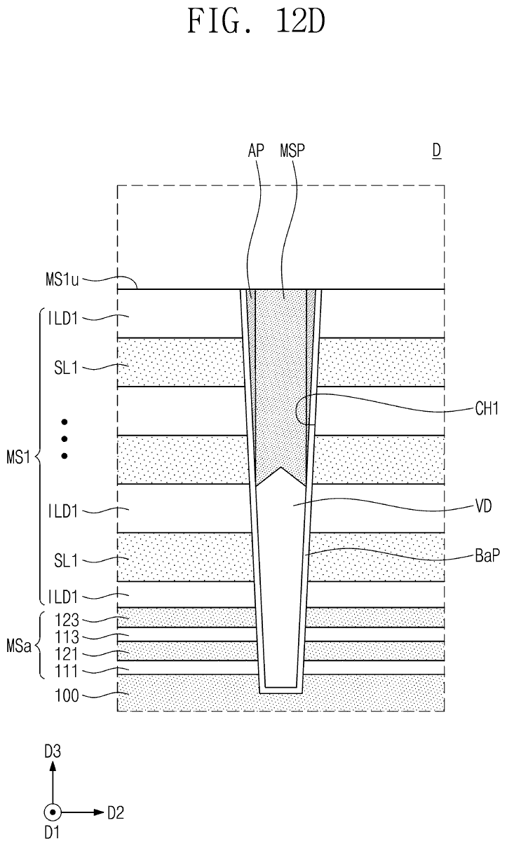

Referring to FIGS. 12A and 12B, an active pattern AP and a mold sacrificial pattern MSP may be formed in an upper portion of each of the first vertical channel holes CH1. In an embodiment, the formation of the active pattern AP and the mold sacrificial pattern MSP may include removing the active layer AL and the mold sacrificial layer MSL on the top surface MS1u of the first mold structure MS1. The partial removal of the active layer AL and the mold sacrificial layer MSL may include planarizing the mold sacrificial layer MSL and the active layer AL to expose the top surface MS1u of the first mold structure MS1. The planarization may be performed using a chemical mechanical polishing (CMP) process or an etch-back process.

Referring to FIGS. 12C and 12D, a barrier pattern BaP, in addition to the active pattern AP and the mold sacrificial pattern MSP, may also be formed in in the upper portion of each of the first vertical channel holes CH1. In an embodiment, the formation of the barrier pattern BaP may include planarizing the mold sacrificial layer MSL, the active layer AL, and the barrier layer Ba to expose the top surface MS1u of the first mold structure MS1.

Referring to FIGS. 5, 6A, 6B, and 13, a second mold structure MS2 may be formed on the first mold structure MS1. In detail, the second mold structure MS2 may be formed on the first mold structure MS1 and the active pattern AP and the mold sacrificial pattern MSP formed in in the upper portion of each of the first vertical channel holes CH1. In an embodiment, the formation of the second mold structure MS2 may include alternately stacking the second interlayer insulating layers ILD2 and second sacrificial layers SL2 on the first mold structure MS1. The second sacrificial layers SL2 may include a material different from the second interlayer insulating layers ILD2. The second sacrificial layers SL2 may include a material having an etch selectivity with respect to the second interlayer insulating layers ILD2. For example, the second sacrificial layers SL2 may include silicon nitride, and the second interlayer insulating layers ILD2 may include silicon oxide. The second sacrificial layers SL2 may be formed to have substantially the same thickness, and at least one of the second interlayer insulating layers ILD2 may be formed to have a different thickness from the others. As an example, the uppermost one of the second interlayer insulating layers ILD2 may be thicker than the others of the second interlayer insulating layers ILD2.

Referring to FIGS. 5, 6A, 6B, and 14, the second vertical channel holes CH2 may be formed. The second vertical channel holes CH2 may be formed to penetrate the second mold structure MS2. The second vertical channel holes CH2 may be vertically overlapped with the first vertical channel holes CH1, respectively. In an embodiment, the formation of the second vertical channel holes CH2 may include forming a mask pattern (not shown) on the second mold structure MS2 and etching the second mold structure MS2 using the mask pattern as an etch mask. The etching process may be performed using an anisotropic etching process. Each of the second vertical channel holes CH2 may have an increasing width in the first or second direction D1 or D2 as a vertical height from the substrate 100 (i.e., in the third direction D3) increases.

Before the formation of the second vertical channel holes CH2, a trimming process may be performed on the second mold structure MS2 on the contact region CCR. The trimming process may include forming a mask pattern to cover a portion of the top surface of the second mold structure MS2 on the cell array region CAR and the contact region CCR, patterning the second mold structure MS2 using the mask pattern as a patterning mask, reducing an area of the mask pattern, and patterning the second mold structure MS2 using the mask pattern having the reduced area as a patterning mask. In an embodiment, the steps of reducing the area of the mask pattern and patterning the second mold structure MS2 using the mask pattern may be repeated several times during the trimming process. As a result of the trimming process, the second mold structure MS2 may have a stepwise structure.

Referring to FIGS. 5, 6A, 6B, and 15, the active pattern AP and the mold sacrificial pattern MSP may be removed from the upper portion of each of the first vertical channel holes CH1. In an embodiment, the removal of the active pattern AP and the mold sacrificial pattern MSP may be achieved by an ashing process or a wet etching process. Next, first and second channel sacrificial patterns CSP1 and CSP2 may be formed to fill the first and second vertical channel holes CH1 and CH2. In detail, the first channel sacrificial pattern CSP1 may be formed to fill each of the first vertical channel holes CH1, and the second channel sacrificial pattern CSP2 may be formed to fill each of the second vertical channel holes CH2.

A first insulating pattern 210 may be formed on the second mold structure MS2. The first insulating pattern 210 may cover a top surface of the second mold structure MS2 (i.e., a top surface of the uppermost one of the second interlayer insulating layers ILD2) and a top surface of the second channel sacrificial pattern CSP2.

Referring to FIGS. 5, 6A, 6B, and 16, a first trench TR1 may be formed to penetrate the first insulating pattern 210, the second mold structure MS2, and the first mold structure MS1. The first trench TR1 may further penetrate at least a portion of the lower mold structure MSa (more specifically, at least a portion of the second semiconductor layer 123). In an embodiment, a bottom surface TR1b of the first trench TR1 may be located at a level lower than a bottom surface of the first mold structure MS1 (i.e., a bottom surface of the lowermost one of the first interlayer insulating layers ILD1) and a top surface of the lower mold structure MSa. Side surfaces of the first and second interlayer insulating layers ILD1 and ILD2 and side surfaces of the first and second sacrificial layers SL1 and SL2 may be exposed by the first trench TR1. The first trench TR1 may be extended from the cell array region CAR toward the contact region CCR.

Referring to FIGS. 5, 6A, 6B, and 17, the first and second sacrificial layers SL1 and SL2 exposed by the first trench TR1 may be selectively removed. The selective removal of the first and second sacrificial layers SL1 and SL2 may be performed through a wet etching process using etching solution. The first and second gate electrodes EL1 and EL2 may be formed to fill empty spaces formed by removing the first and second sacrificial layers SL1 and SL2. As a result, the stack ST including the first and second gate electrodes EL1 and EL2 and the first and second interlayer insulating layers ILD1 and ILD2 may be formed.

Since the first and second gate electrodes EL1 and EL2 are formed before the formation of the vertical channel structures VS, it may be possible to prevent the vertical channel structures VS from being partially etched when the first and second sacrificial layers SL1 and SL2 are removed. This may make it possible to improve the electrical and reliability characteristics of the semiconductor device.

The separation spacer 130 and a sacrificial separation pattern 140 may be formed to fill the first trench TR1. The separation spacer 130 and the sacrificial separation pattern 140 may be extended from the cell array region CAR toward the contact region CCR.

Referring to FIGS. 5, 6A, 6B, and 18, a second insulating pattern 220 may be formed to cover a portion of a top surface of the first insulating pattern 210. An etching process may be performed using the second insulating pattern 220 as a mask. As a result of the etching process, a first opening OP1 may be formed. The first opening OP1 may be formed to expose a portion of the top surface of the stack ST and the top surface of the second channel sacrificial pattern CSP2. The first opening OP1 may not expose the separation spacer 130 and the sacrificial separation pattern 140. For example, the first and second insulating patterns 210 and 220 may cover the separation spacer 130 and the sacrificial separation pattern 140.

Referring to FIGS. 5, 6A, 6B, and 19, the second channel sacrificial pattern CSP2 and the first channel sacrificial pattern CSP1 exposed by the first opening OP1 may be removed. The vertical channel structures VS may be formed on the cell array region CAR to fill a space (i.e., the vertical channel holes CH), which is formed by removing the first and second channel sacrificial patterns CSP1 and CSP2. Similarly, the dummy vertical channel structures DVS may be formed on the contact region CCR to fill the vertical channel holes CH.

The formation of each of the vertical channel structures VS and the dummy vertical channel structures DVS may include forming the data storage pattern DSP to conformally cover the inner side surface of each of the vertical channel holes CH, forming the vertical semiconductor pattern VSP to conformally cover the side surface of the data storage pattern DSP, forming the insulating gapfill pattern VI to fill at least a portion of a space enclosed by the vertical semiconductor pattern VSP, and forming the conductive pad PAD to fill a space enclosed by the vertical semiconductor pattern VSP and the insulating gapfill pattern VI. Referring to FIG. 7A, the formation of the data storage pattern DSP may include sequentially depositing the blocking insulating layer BLK, the charge storing layer CIL, and the tunneling insulating layer TIL on the inner side surface of each of the vertical channel holes CH.

The first and second insulating patterns 210 and 220 may be removed, after the formation of the vertical channel structures VS. Furthermore, the separation spacer 130 and the sacrificial separation pattern 140 may also be partially etched during the removing of the first insulating pattern 210, and the top surface of the stack ST may be exposed to the outside.

Referring to FIGS. 5, 6A, 6B, and 20, a third insulating pattern 230 may be formed on the top surface of the stack ST. The third insulating pattern 230 may correspond to the third insulating layer 230 described with reference to FIGS. 6A and 6B.

The third insulating pattern 230 may be formed to expose a top surface of the sacrificial separation pattern 140 to the outside. The second trench TR2 may be formed by selectively removing the sacrificial separation pattern 140 exposed by the third insulating pattern 230. In an embodiment, at least a portion of the lower mold structure MSa on the cell array region CAR may be removed during the process of removing the sacrificial separation pattern 140. The lower mold structure MSa on the contact region CCR may not be removed.

The second trench TR2 may be extended from the cell array region CAR toward the contact region CCR. On the cell array region CAR, a bottom surface TR2b of the second trench TR2 may be located between a top surface of the first semiconductor layer 121 and the top surface of the substrate 100.

Referring to FIGS. 5, 6A, 6B, and 21, the first semiconductor layer 121 exposed through the second trench TR2 may be selectively removed. The selective removal of the first semiconductor layer 121 may be performed through a wet etching process using etching solution. As a result of the removal of the first semiconductor layer 121, a first horizontal cavity HC1 may be formed between a top surface of the first buffer insulating layer 111 and a bottom surface of the second buffer insulating layer 113. The first horizontal cavity HC1 may mean an empty space between the first and second buffer insulating layers 111 and 113. A portion of the data storage pattern DSP of each of the vertical channel structures VS may be exposed by the first horizontal cavity HC1.

The removal of the first semiconductor layer 121 may be performed on the cell array region CAR, and the lower mold structure MSa (e.g., a portion of the first semiconductor layer 121) on the contact region CCR may be left.

Referring to FIGS. 5, 6A, 6B, and 22, a second horizontal cavity HC2 may be formed by removing the first and second buffer insulating layers 111 and 113 exposed by the first horizontal cavity HC1. The second horizontal cavity HC2 may mean an empty space between the substrate 100 and the second semiconductor layer 123. In addition, a portion of the data storage pattern DSP, which is exposed by the second horizontal cavity HC2, may be removed. A portion of the vertical semiconductor pattern VSP of each of the vertical channel structures VS may be exposed by the second horizontal cavity HC2.

The removal of the first and second buffer insulating layers 111 and 113 may be performed on the cell array region CAR, and the lower mold structure MSa on the contact region CCR (especially, a portion of each of the first and second buffer insulating layers 111 and 113 provided on the contact region CCR) may remain as it is.

Referring to FIGS. 5, 6A, 6B, and 23, the first source conductive pattern SCP1 may be formed to fill the second horizontal cavity HC2. Although not shown, an air gap may be formed in the first source conductive pattern SCP1. The second semiconductor layer 123 on the cell array region CAR may be referred to as the second source conductive pattern SCP2, and as a result, the source structure SC including the first and second source conductive patterns SCP1 and SCP2 may be formed.

Referring back to FIGS. 5, 6A, and 6B, the separation structure 160 may be formed to fill the second trench TR2. The top surface of the separation structure 160 may be coplanar with a top surface of the third insulating layer 230.

Thereafter, the bit line contact plugs BLCP may be formed to penetrate the third insulating layer 230, the cell contact plugs CCP may be formed to penetrate the third insulating layer 230 and the second insulating layer 170, and the peripheral contact plug TCP may be formed to penetrate the third insulating layer 230, the second insulating layer 170, and at least a portion of the first insulating layer 30. The bit lines BL connected to the bit line contact plugs BLCP, the first conductive lines CL1 connected to the cell contact plugs CCP, and the second conductive line CL2 connected to the peripheral contact plug TCP may be formed on the third insulating layer 230.

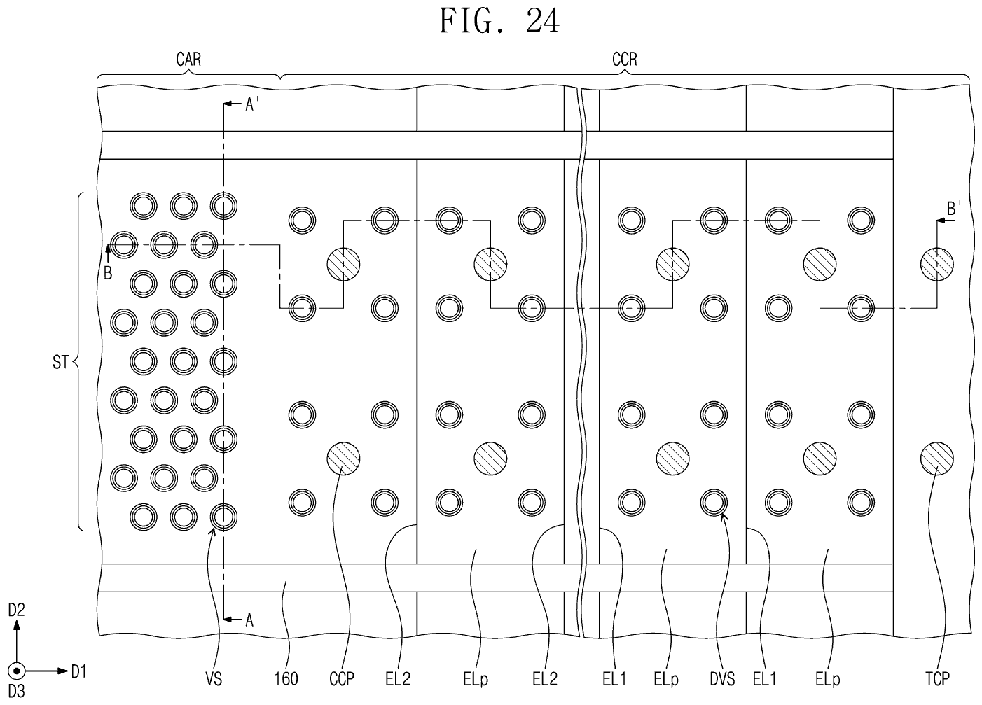

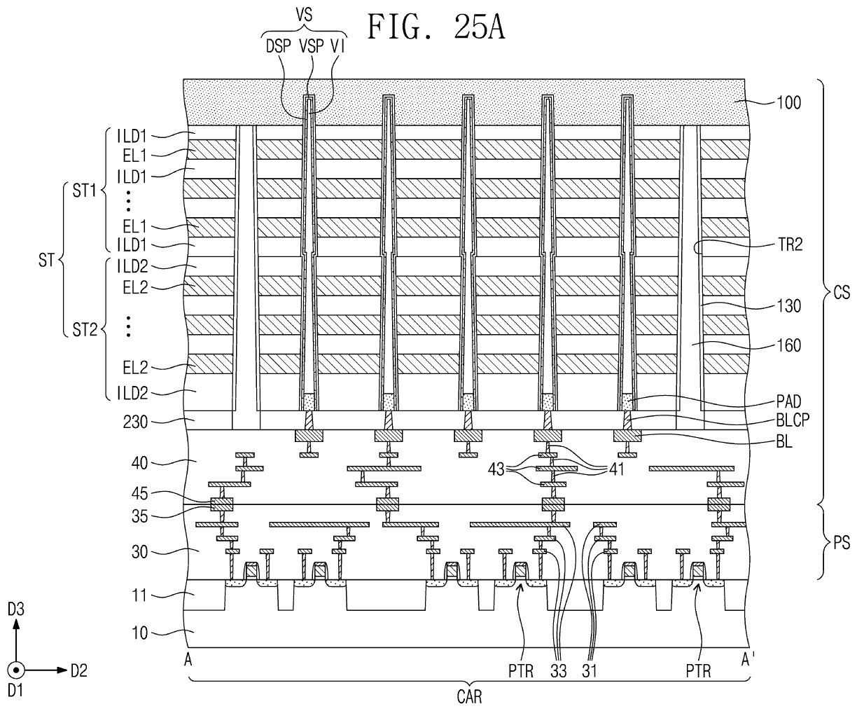

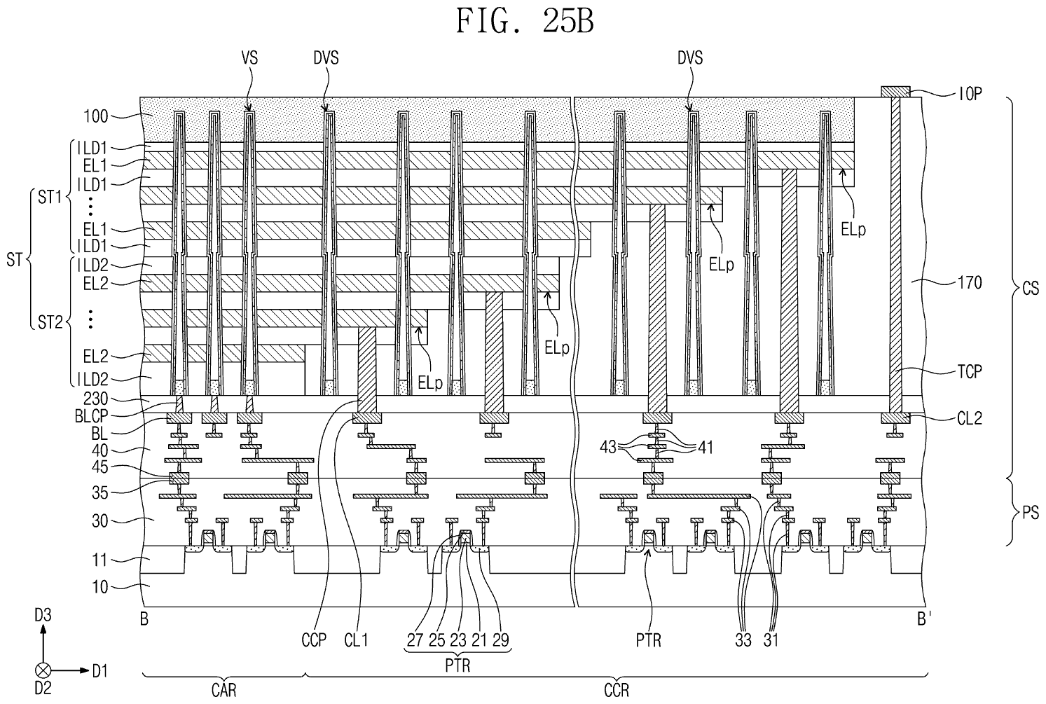

FIG. 24 is a plan view illustrating a semiconductor device according to an embodiment of the inventive concept. FIGS. 25A and 25B are sectional views, which are respectively taken along lines A-A′ and B-B′ of FIG. 24 to illustrate a semiconductor device according to an embodiment of the inventive concept. Hereinafter, an element previously described with reference to FIGS. 5, 6A, and 6B may be identified by the same reference number without repeating an overlapping description thereof, for convenience in description.

Referring to FIGS. 24, 25A, and 25B, the peripheral circuit structure PS may be provided on the first substrate 10. In an embodiment, the peripheral circuit structure PS may include the peripheral circuit transistors PTR, the peripheral contact plugs 31, the peripheral circuit interconnection lines 33 electrically connected to the peripheral circuit transistors PTR through the peripheral contact plugs 31, first bonding pads 35 electrically connected to the peripheral circuit interconnection lines 33, and the first insulating layer 30 enclosing the peripheral circuit transistors PTR, the peripheral contact plugs 31, the peripheral circuit interconnection lines 33, and the first bonding pads 35. The first insulating layer 30 may not cover top surfaces of the first bonding pads 35. A top surface of the first insulating layer 30 may be coplanar with the top surfaces of the first bonding pads 35.

The cell array structure CS, which includes second bonding pads 45, the stack ST, and the substrate 100, may be provided on the peripheral circuit structure PS. The substrate 100 may be provided on the stack ST. The stack ST may be provided between the substrate 100 and the peripheral circuit structure PS.

The second bonding pads 45, connection contact plugs 41, connection circuit interconnection lines 43, and a fourth insulating layer 40 may be provided on the first insulating layer 30. Here, the second bonding pads 45 may be provided to be in contact with the first bonding pads 35 of the peripheral circuit structure PS, the connection circuit interconnection lines 43 may be electrically connected to the second bonding pads 45 through the connection contact plugs 41, and the fourth insulating layer 40 may be provided to enclose the second bonding pads 45, the connection contact plugs 41, and the connection circuit interconnection lines 43. The fourth insulating layer 40 may have a multi-layered structure including a plurality of insulating layers. For example, the fourth insulating layer 40 may be formed of or include at least one of silicon oxide, silicon nitride, silicon oxynitride, and/or low-k dielectric materials. A width of the connection contact plugs 41 in the first or second direction D1 or D2 may decrease as a height in the third direction D3 increases or a distance from the peripheral substrate 10 increases. The connection contact plugs 41 and the connection circuit interconnection lines 43 may include at least one of metal or conductive materials.

The fourth insulating layer 40 may not cover bottom surfaces of the second bonding pads 45. A bottom surface of the fourth insulating layer 40 may be substantially coplanar with the bottom surfaces of the second bonding pads 45. A bottom surface of each of the second bonding pads 45 may be in direct contact with a top surface of each of the first bonding pads 35. The first and second bonding pads 35 and 45 may be formed of or include at least one of metallic materials (e.g., copper (Cu), tungsten (W), aluminum (Al), nickel (Ni), or tin (Sn)). For example, the first and second bonding pads 35 and 45 may be formed of or include copper (Cu). The first and second bonding pads 35 and 45 may be connected to each other without any interface therebetween to form a single object. The side surfaces of the first and second bonding pads 35 and 45 are illustrated to be aligned to each other, but the present invention is not limited to this example. For example, the side surfaces of the first and second bonding pads 35 and 45 may be spaced apart from each other, when viewed in a plan view.

The bit lines BL and the first and second conductive lines CL1 and CL2, which are in contact with the connection contact plugs 41, may be provided in an upper portion of the fourth insulating layer 40. The third insulating layer 230 may be provided on the fourth insulating layer 40, and the stack ST and the second insulating layer 170 may be provided on the third insulating layer 230.

As a distance from the peripheral substrate 10 increases in the third direction D3, the first gate electrodes EL1 of the first stack ST1 and the second gate electrodes EL2 of the second stack ST2 may have an increasing length in the first direction D1. The side surfaces of the first and second gate electrodes EL1 and EL2 may be spaced apart from each other by a specific distance in the first direction D1, when viewed in the plan view of FIG. 24. The lowermost one of the second gate electrodes EL2 of the second stack ST2 may have the smallest length in the first direction D1, and the uppermost one of the first gate electrodes EL1 of the first stack ST1 may have the largest length in the first direction D1. As a distance from the peripheral substrate 10 increases in the third direction D3, the first and second interlayer insulating layers ILD1 and ILD2 may have an increasing length in the first direction D1, similar to the first and second gate electrodes EL1 and EL2.

The bit line contact plugs BLCP, the cell contact plugs CCP, the peripheral contact plug TCP, the vertical channel structures VS, and the dummy vertical channel structures DVS may have a decreasing width in the first or second direction D1 or D2, as a height in the third direction D3 increases. A width of the separation structure 160 in the second direction D2 may decrease as a heigh in the third direction D3 increases.

An input/output pad IOP, which is electrically connected to at least one of the peripheral circuit transistors PTR of the peripheral circuit structure PS through the peripheral contact plug TCP, may be provided on the second insulating layer 170. The input/output pad IOP may correspond to the input/output pad 1101 of FIG. 1 or one of the input/output pads 2210 of FIGS. 3 and 4.

Since the cell array structure CS is placed on the peripheral circuit structure PS, a cell capacity per unit area in the semiconductor device may be increased. In addition, the peripheral circuit structure PS and the cell array structure CS may be separately fabricated and then may be coupled to each other, and in this case, it may be possible to prevent the peripheral circuit transistors PTR from being damaged by several thermal treatment processes. Accordingly, the electrical and reliability characteristics of the semiconductor device may be improved.

According to an embodiment of the inventive concept, a void may be intentionally formed in each of vertical channel holes penetrating a mold structure. In this case, it may be possible to prevent a crack or warpage issue from occurring in the mold structure by a stress. Accordingly, a semiconductor device with improved electrical and reliability characteristics may be provided.

While example embodiments of the inventive concept have been particularly shown and described, it will be understood by one of ordinary skill in the art that variations in form and detail may be made therein without departing from the spirit and scope of the present invention as set forth in the attached claims.

What is claimed is:

1. A method of fabricating a semiconductor device, the method comprising:
forming a lower mold structure on a substrate;
forming a first mold structure on the lower mold structure, the first mold structure including first interlayer insulating layers and first sacrificial layers, which are alternately stacked in a vertical direction;
forming first vertical channel holes to penetrate the first mold structure, the lower mold structure, and a portion of the substrate; and
forming an active layer to cover a top surface of the first mold structure and extend to an upper side surface of each of the first vertical channel holes,
wherein the active layer includes a horizontal portion covering the top surface of the first mold structure and a vertical portion covering the upper side surface of each of the first vertical channel holes, and
wherein the active layer includes a metallic material.

2. The method of claim 1, wherein a vertical length of the vertical portion is 15% to 50% of a hole length of each of the first vertical channel holes, when measured in the vertical direction.

3. The method of claim 1, further comprising:
forming a mold sacrificial layer on the active layer to fill an upper portion of each of the first vertical channel holes; and
forming a void in a remaining portion of each of the first vertical channel holes.

4. The method of claim 3, further comprising:
removing the active layer and the mold sacrificial layer from the top surface of the first mold structure to form an active pattern and a mold sacrificial pattern in the upper portion of each of the first vertical channel holes.

5. The method of claim 4, further comprising:
forming a second mold structure on the first mold structure to include second interlayer insulating layers and second sacrificial layers, which are alternately stacked in the vertical direction.

6. The method of claim 5, further comprising:
forming second vertical channel holes to pass through the second mold structure,
wherein the second vertical channel holes are vertically overlapped with the first vertical channel holes, respectively.

7. The method of claim 1, further comprising:
forming a barrier layer to conformally cover side and bottom surfaces of each of the first vertical channel holes and to extend to a region on the top surface of the first mold structure, after the forming of the first vertical channel holes and before the forming of the active layer.

8. The method of claim 7, further comprising:
forming a mold sacrificial layer on the active layer to fill an upper portion of each of the first vertical channel holes and to form a void in a remaining portion of each of the first vertical channel holes;
removing the active layer and the mold sacrificial layer from the top surface of the first mold structure to form an active pattern and a mold sacrificial pattern in the upper portion of each of the first vertical channel holes; and
removing the barrier layer from the top surface of the first mold structure to form a barrier pattern in the side and bottom surfaces of each of the first vertical channel holes.

9. The method of claim 8, further comprising:
forming a second mold structure, which includes second interlayer insulating layers and second sacrificial layers alternately stacked in the vertical direction, on the first mold structure; and
forming second vertical channel holes to penetrate the second mold structure,
wherein the second vertical channel holes are vertically overlapped with the first vertical channel holes, respectively.

10. A method of fabricating a semiconductor device, the method comprising:
forming a first mold structure on a substrate, the first mold structure including first interlayer insulating layers and first sacrificial layers alternately stacked in a vertical direction;
forming a vertical channel hole to penetrate the first mold structure; and
forming an active layer to cover a top surface of the first mold structure and extend to an upper side surface of the vertical channel hole,
wherein the active layer includes a horizontal portion covering the top surface of the first mold structure and a vertical portion covering the upper side surface of the vertical channel hole, and
wherein a width of the vertical portion, which is measured in a horizontal direction parallel to a top surface of the substrate, increases as a distance from the substrate increases.

11. The method of claim 10, wherein the active layer includes a metallic material.

12. The method of claim 11, wherein the active layer comprises boron (B).

13. The method of claim 10, wherein a vertical length of the vertical portion is 15% to 50% of a hole length of the vertical channel hole, when measured in the vertical direction.

14. The method of claim 10, further comprising:
forming a mold sacrificial layer on the active layer to fill an upper portion of the vertical channel hole; and
forming a void in a remaining portion of the vertical channel hole.

15. The method of claim 14, wherein an upper portion of the void has a cone shape.

16. The method of claim 14, further comprising:
removing the active layer and the mold sacrificial layer from the top surface of the first mold structure to form an active pattern and a mold sacrificial pattern in the upper portion of the vertical channel hole.

17. The method of claim 16, further comprising:
forming a second mold structure on the first mold structure, the second mold structure including second interlayer insulating layers and second sacrificial layers alternately stacked in the vertical direction.

18. The method of claim 10, further comprising:
forming a barrier layer to conformally cover side and bottom surfaces of the vertical channel hole and extend to the top surface of the first mold structure, after the forming of the vertical channel hole and before the forming of the active layer.

19. A method of fabricating a semiconductor device, the method comprising:
forming a first mold structure on a substrate to include first interlayer insulating layers and first sacrificial layers alternately stacked in a vertical direction;
forming first vertical channel holes to penetrate the first mold structure and a portion of the substrate;
forming an active layer to cover a top surface of the first mold structure and extend to an upper side surface of each of the first vertical channel holes;
forming a mold sacrificial layer on the active layer to fill an upper portion of each of the first vertical channel holes;
forming a void in a remaining portion of each of the first vertical channel holes;
forming a second mold structure on the first mold structure to include second interlayer insulating layers and second sacrificial layers alternately stacked in the vertical direction, after removing the active layer and the mold sacrificial layer from the top surface of the first mold structure;
forming second vertical channel holes to penetrate the second mold structure and each of the second vertical channel holes vertically overlapped with each of the first vertical channel holes;
forming a first stack by filling empty spaces formed by removing the first sacrificial layers to include the first interlayer insulating layers and first gate electrodes alternately stacked in the vertical direction; and
forming a second stack by filling empty spaces formed by removing the second sacrificial layers to include the second interlayer insulating layers and second gate electrodes alternately stacked in the vertical direction.

20. The method of claim 19, the uppermost one of the first interlayer insulating layers of the first mold structure includes boron (B) on a top surface thereof and a side surface adjacent to each of the first vertical channel holes.
